(19) United States
(12) Patent Application Publication
(10) Pub. No.: US 2025/0221125 A1
(43) Pub. Date: Jul. 3, 2025

(54) METHOD AND APPARATUS FOR FABRICATING DISPLAY DEVICE

(71) Applicant: Samsung Display Co., LTD., Yongin-si (KR)

(72) Inventors: Jung Gun NAM, Yongin-si (KR); Eun A YANG, Yongin-si (KR)

(21) Appl. No.: 18/890,282

(22) Filed: Sep. 19, 2024

(30) Foreign Application Priority Data
Dec. 29, 2023 (KR) 10-2023-0197273

(51) Int. Cl. H01L 27/15; H01L 21/67

(52) U.S. Cl. CPC H10H 29/142; H01L 21/67144

(57) ABSTRACT

A method of fabricating a display device includes preparing a transfer device including a printing substrate and a stamp; supplying an ink containing light-emitting elements onto the printing substrate; picking up the light-emitting elements with the stamp; and transferring the light-emitting elements to a target substrate, the light-emitting elements being aligned on the printing substrate or the stamp.

### CROSS-REFERENCE TO RELATED APPLICATION

The present application claims priority to and the benefit of Korean Patent Application No. 10-2023-0197273, filed on Dec. 29, 2023, in the Korean Intellectual Property Office, the entire disclosure of which is incorporated by reference herein.

### BACKGROUND

### 1. Field

Embodiments of the present disclosure relate to a method and an apparatus for fabricating a display device.

### 2. Description of the Related Art

Display devices for displaying images become more and more important as multimedia technology evolves. Accordingly, a variety of types of display devices, including light-emitting display devices, are under development. A light-emitting display device includes pixels including light-emitting elements.

### SUMMARY

Aspects and features of embodiments of the present disclosure provide a method and an apparatus for fabricating a high-resolution display device including light-emitting elements.

However, aspects and features of embodiments of the present disclosure are not restricted to the one set forth herein. The above and other aspects and features of embodiments of the present disclosure will become more apparent to one of ordinary skill in the art to which the present disclosure pertains by referencing the detailed description of the present disclosure given below.

In one or more embodiments, a method of fabricating a display device, the method includes: preparing a transfer device including a printing substrate and a stamp; supplying an ink containing light-emitting elements onto the printing substrate; picking up the light-emitting elements with the stamp; and transferring the light-emitting elements to a target substrate, the light-emitting elements being aligned on the printing substrate or the stamp.

In one or more embodiments, the preparing the transfer device includes: preparing the stamp including a first alignment electrode and a second alignment electrode; and a capping layer covering the first alignment electrode and the second alignment electrode.

In one or more embodiments, the picking up the light-emitting elements with the stamp includes: aligning the light-emitting elements by bringing the stamp into contact with the ink on the printing substrate and applying an alignment signal to the first alignment electrode and the second alignment electrode; and drying the ink and fixing the light-emitting elements on the stamp.

In one or more embodiments, the preparing the transfer device includes: preparing the printing substrate including a support substrate and a bank on the support substrate, the bank defining a light-emitting element supply area.

In one or more embodiments, the preparing the transfer device includes: preparing the printing substrate including at least two light-emitting element supply areas adjacent to each other in a first direction; and preparing the stamp including at least two pickup portions adjacent to each other in the first direction and having different heights.

In one or more embodiments, the picking up the light-emitting elements with the stamp includes: picking up light-emitting elements of different sizes supplied to the at least two light-emitting element supply areas on the at least two pickup portions, respectively.

In one or more embodiments, the transferring the light-emitting elements to the target substrate includes: concurrently transferring the light-emitting elements of different sizes to the target substrate.

In one or more embodiments, the preparing the transfer device includes: preparing the printing substrate including a support substrate, a liquid-repellent bank located entirely on the support substrate, a first alignment electrode and a second alignment electrode on the liquid-repellent bank, and a capping layer covering the first alignment electrode and the second alignment electrode.

In one or more embodiments, the aligning the light-emitting elements includes: aligning the light-emitting elements by applying an alignment signal to the first alignment electrode and the second alignment electrode as the ink is supplied on the printing substrate; and drying the ink.

In one or more embodiments, the picking up the light-emitting elements with the stamp includes: transferring the light-emitting elements to the stamp, the light-emitting elements being aligned on the printing substrate.

In one or more embodiments, the method further includes: forming a first electrode and a second electrode on both ends of the light-emitting elements on the target substrate after the transferring the light-emitting elements to the target substrate.

In one or more embodiments, an apparatus for fabricating a display device, the apparatus includes: a printing substrate including light-emitting element supply areas; and a stamp including a pickup portion for picking up light-emitting elements supplied on the printing substrate, wherein one of the printing substrate and the stamp includes a first alignment electrode, a second alignment electrode, and a capping layer covering the first alignment electrode and the second alignment electrode.

In one or more embodiments, the first alignment electrode, the second alignment electrode, and the capping layer are on the pickup portion of the stamp.

In one or more embodiments, the printing substrate includes a support substrate and a bank on the support substrate, the bank partitioning the light-emitting element supply areas.

In one or more embodiments, the pickup portion includes a first pickup portion and a second pickup portion having different heights.

In one or more embodiments, the printing substrate includes a plurality of light-emitting element supply areas arranged along at least a first direction.

In one or more embodiments, the first pickup portion and the second pickup portion are spaced from each other by a distance corresponding to a distance between two light-emitting element supply areas adjacent each other in the first direction.

In one or more embodiments, the first alignment electrode, the second alignment electrode, and the capping layer are at the printing substrate.

In one or more embodiments, the printing substrate further includes: a support substrate and a liquid-repellent bank located entirely on the support substrate.

In one or more embodiments, the first alignment electrode, the second alignment electrode, and the capping layer are on a portion of the liquid-repellent bank and expose another portion of the liquid-repellent bank.

According to one or more embodiments of the present disclosure, light-emitting elements can be properly disposed on a target substrate, such as a lower substrate of a display device, using a printing substrate and a stamp. Specifically, according to embodiments, light-emitting elements may be supplied on a printing substrate, and then the light-emitting elements may be picked up with a stamp and transferred to a target substrate. One of the printing substrate and the stamp according to the embodiments may include alignment electrodes, and thus the light-emitting elements can be transferred to the target substrate as they are aligned on the printing substrate or the stamp. According to the embodiments of the present disclosure, a high-resolution display device can be easily fabricated.

However, effects, aspects, and features of the present disclosure are not limited to those discussed above and various other effects, aspects, and features are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view showing a display device according to one or more embodiments of the present disclosure.

FIG. 2 is a plan view showing a display area of a display device according to one or more embodiments of the present disclosure.

FIG. 3 is a plan view showing a display area of a display device according to one or more embodiments of the present disclosure.

FIG. 4 is a cross-sectional view showing a display device according to one or more embodiments of the present disclosure.

FIG. 5 is a cross-sectional view showing a display device according to one or more embodiments of the present disclosure.

FIG. 6 is a cross-sectional view showing a display device according to one or more embodiments of the present disclosure.

FIG. 7 is a cross-sectional view showing a display device according to one or more embodiments of the present disclosure.

FIG. 8 is a perspective cutaway view showing a light-emitting element according to one or more embodiments of the present disclosure.

FIG. 9 is a flowchart for illustrating a method of fabricating a display device according to one or more embodiments of the present disclosure.

FIG. 10 is a perspective view schematically showing a printing substrate according to one or more embodiments.

FIG. 11 is a plan view showing a printing substrate according to one or more embodiments of the present disclosure.

FIG. 12 is a plan view showing a printing substrate according to an embodiment of the present disclosure.

FIG. 13 is a cross-sectional view showing a printing substrate according to one or more embodiments of the present disclosure.

FIG. 14 is a perspective view showing a stamp according to one or more embodiments of the present disclosure.

FIG. 15 is a perspective view showing a stamp according to one or more embodiments of the present disclosure.

FIGS. 16-22 are cross-sectional views showing a method of fabricating a display device according to one or more embodiments.

FIG. 23 is a perspective view showing a stamp according to one or more embodiments of the present disclosure.

FIG. 24 is a perspective view showing a stamp according to one or more embodiments of the present disclosure.

FIG. 25 is a cross-sectional view showing a method of concurrently (e.g., simultaneously) transferring light-emitting elements of different sizes using a stamp according to one or more embodiments.

FIG. 26 is a plan view showing a printing substrate according to one or more embodiments of the present disclosure.

FIG. 27 is a cross-sectional view showing a printing substrate according to one or more embodiments of the present disclosure.

FIG. 28 is a cross-sectional view showing a stamp according to one or more embodiments of the present disclosure.

FIGS. 29-32 are cross-sectional views showing a method of fabricating a display device according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to embodiments set forth herein. Rather, these embodiments are provided so that the present disclosure will be thorough and complete, and will fully convey the scope of the present disclosure to those skilled in the art.

It will also be understood that when an element or a layer is referred to as being “on” another element or layer, it can be directly on the other element or layer, or intervening layers may also be present. The same reference numbers indicate the same components throughout the present disclosure.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Herein, “A and/or B” may indicate only A, only B, or both A and B. Also, “at least one of A and B” herein may indicate only A, only B, or both A and B.

Features of each of various embodiments of the present disclosure may be

partially or entirely combined with each other and may technically variously interwork with each other, and respective embodiments may be implemented independently of each other or may be implemented together in association with each other.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described in detail with reference to the accompanying drawings.

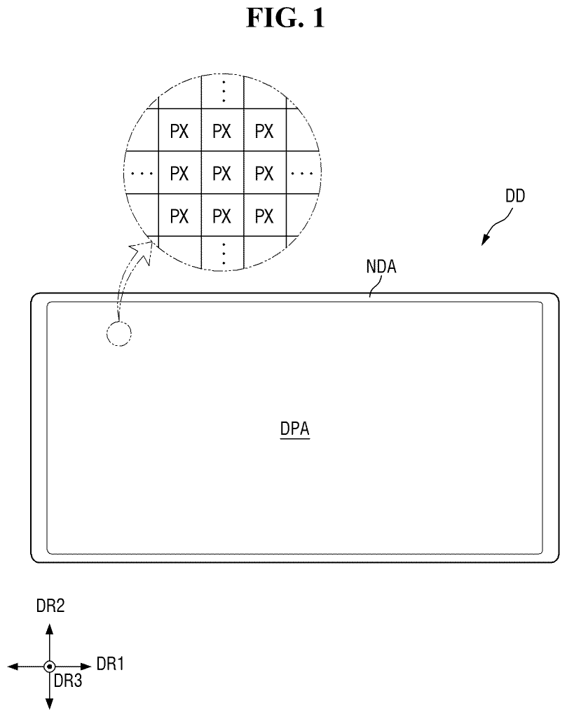

FIG. 1 is a plan view showing a display device DD according to one or more embodiments of the present disclosure.

Referring to FIG. 1, a display device DD for display images may refer to any electronic device that provides a display screen. For example, the display device DD may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

The display device DD includes a display panel for providing a display screen. According to one or more embodiments of the present disclosure, the display device DD may be a light-emitting display device and may include a display panel including light-emitting elements. FIG. 1 shows a schematic shape of the display device DD with such a display panel.

In FIG. 1, a first direction DR1, a second direction DR2 and a third direction DR3 are indicated. The first direction DR1 may be the horizontal direction or row direction of the display device DD. The second direction DR2 may intersect the first direction DR1 and, for example, may be the vertical direction or column direction of the display device DD. The third direction DR3 may intersect the first direction DR1 and the second direction DR2 and may be the thickness direction or height direction of the display device DD, for example.

The display device DD may have a variety of shapes. For example, the display device DD may have shapes such as a rectangle with longer lateral sides, a rectangle with longer vertical sides, a square, a quadrangle with rounded corners, other non-rectangular polygons, a circle, an oval, and/or any other shape.

The display device DD may include a display area DPA where images are displayed. According to one or more embodiments of the present disclosure, the shape of the display area DPA may be similar to the overall shape of the display device DD. According to the embodiment of FIG. 1, the display device DD and the display area DPA have a rectangular shape with longer lateral sides and rounded corners.

The display device DD may include the display area DPA and a non-display area NDA around an edge or a periphery of the display area DPA. In the display area DPA, images may be displayed. The non-display area NDA may refer to the other area than the display area DPA. The display area DPA may generally occupy the center of the display device DD.

The display area DPA may include pixels PX. The pixels PX may be arranged in the display area DPA in a matrix or other pattern. For example, the pixels PX may be arranged along rows and columns of a matrix. Each of the pixels PX may have, but is not limited to, a rectangular shape, a square shape, or a diamond shape when viewed from the top.

Each of the pixels PX may include at least one light-emitting element that emits light of a particular color. For example, each of the pixels PX may include at least one light-emitting element that emits light of red, green, blue, white, or other colors.

The non-display area NDA may be disposed around the display area DPA. The non-display area NDA may surround the display area DPA entirely or partially. Lines or circuit drivers included in the display device DD may be disposed or external devices may be mounted in the non-display area NDA.

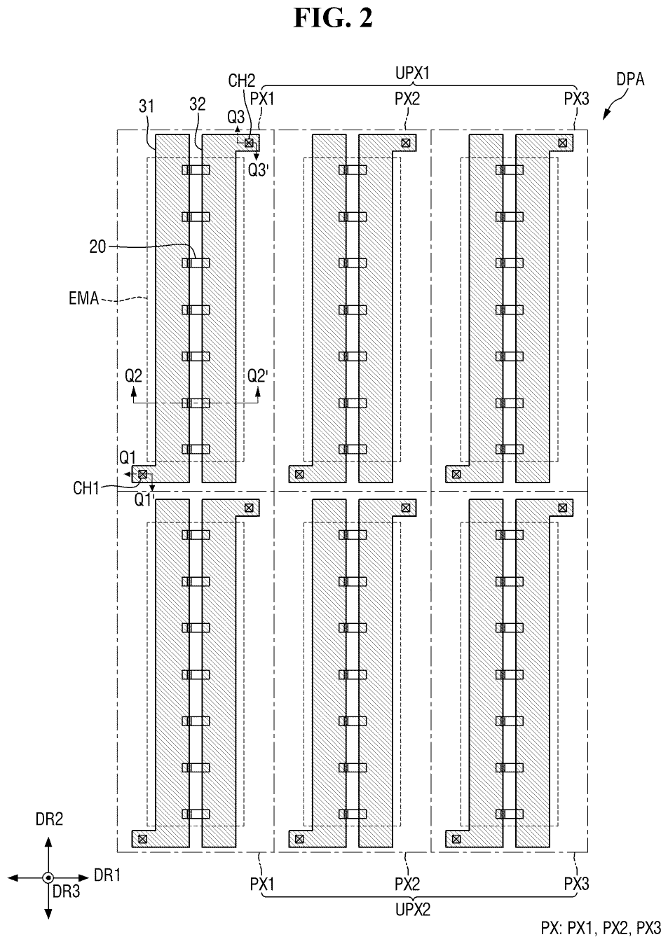

FIG. 2 is a plan view showing the display area DPA of the display device DD according to one or more embodiments of the present disclosure. For example, FIG. 2 shows a part of the display area DPA where some pixels PX of FIG. 1 are arranged. FIG. 2 shows a schematic structure of the pixels PX, focusing on the light-emitting elements 20 provided in each of the pixels PX and first electrodes 31 and second electrodes 32 connected to the light-emitting elements 20.

Referring to FIGS. 1 and 2, the display device DD may include a number of pixels PX arranged in the display area DPA. For example, the display device DD may include first pixels PX1 emitting light of a first color (e.g., first color sub-pixels), second pixels PX2 emitting light of a second color (e.g., second color sub-pixels), and third pixels PX3 emitting light of a third color (e.g., third color sub-pixels). According to one or more embodiments of the present disclosure, the first color may be red, the second color may be green, and the third color may be blue. It is, however, to be understood that the present disclosure is not limited thereto. At least one first pixel PX1, at least one second pixel PX2, and at least one third pixel PX3 adjacent to one another may form each unit pixel UPX capable of emitting light of various colors. For example, a first pixel PX1, a second pixel PX2, and a third pixel PX3 arranged sequentially along the first direction DR1 in the Kth row of the display area DPA may form a first unit pixel UPX1, and a first pixel PX1, a second pixel PX2, and a third pixel PX3 arranged sequentially along the first direction DR1 in the (K+¹)^{th} row of the display area DPA may form a second unit pixel UPX2, where K is a natural number. The number, type, and/or arrangement structure of the pixels PX form each unit pixel may vary depending on the embodiments.

Each of the pixels PX may include light-emitting elements 20, and a first electrode 31 and a second electrode 32 connected to different ends of the light-emitting elements 20, respectively. According to one or more embodiments of the present disclosure, each of the pixels PX may include a plurality of light-emitting elements 20 disposed in the emission area EMA.

In the emission area EMA, at least one light-emitting element 20 may be disposed to emit light of a particular wavelength range. For example, the emission area EMA may include an area where a plurality of light-emitting elements 20 is disposed in a pixel area where each of the pixels PX is disposed, and may include an area where lights emitted from the light-emitting elements 20 exit.

According to one or more embodiments of the present disclosure, the first pixels PX1, the second pixels PX2, and/or the third pixels PX3 may include light-emitting elements 20 that emit lights of different colors. For example, the first pixels PX1, the second pixels PX2, and the third pixels PX3 may include light-emitting elements 20 that emit first color light, second color light, and third color light, respectively. Alternatively, the first pixels PX1, the second pixels PX2, and the third pixels PX3 may include light-emitting elements 20 that emit lights of the same color (e.g., blue light or white light). In the emission areas EMA of the first pixels PX1, the second pixels PX2, and/or the third pixels PX3, light conversion patterns (e.g., wavelength conversion patterns containing quantum dots) and/or color filters for converting and/or controlling the colors of lights emitted from the light-emitting elements 20 provided in each of the pixels PX may be disposed.

According to one or more embodiments of the present disclosure, the light-emitting elements 20 may be arranged and/or aligned with orientation in the emission area EMA of each of the pixels PX. For example, in each of the emission areas EMA, the light-emitting elements 20 may be arranged substantially along the second direction DR2, and the light-emitting elements 20 may be arranged substantially along the first direction DR1. For example, each of the light-emitting elements 20 may include a first end (e.g., a P-type end) that overlaps with the first electrode 31 and is connected to the first electrode 31, and a second end (e.g., an N-type end) that overlaps with the second electrode 32 and is connected to the second electrode 32. According to one or more embodiments of the present disclosure, at least one inactive light-emitting element (e.g., a dummy light-emitting element) may be disposed in the emission area EMA of each of the pixels PX, which is not properly connected or is reversely connected between the first electrode 31 and the second electrode 32 and thus does not contribute to emission of pixels PX. FIG. 2 shows only the light-emitting elements 20 that contribute to the emission of the pixels PX. Although the same number of light-emitting elements 20 are disposed in different pixels PX in FIG. 2, the present disclosure is not limited thereto. For example, the pixels PX may include a similar number of light-emitting elements 20. In addition, although each of the light-emitting elements 20 is aligned exactly in the first direction DR1 in FIG. 2, some of the light-emitting elements 20 may be aligned in a diagonal direction inclined with respect to the first direction DR1 and the second direction DR2, and the first and second ends may be properly connected to the first electrode 31 and the second electrode 32, respectively. In addition, although the light-emitting elements 20 are arranged at uniform intervals in FIG. 2, the light-emitting elements 20 may be arranged at non-uniform intervals.

The first electrode 31 and the second electrode 32 may face each other. For example, the first electrode 31 and the second electrode 32 may be spaced from each other by a distance less than or equal to the length of the light-emitting elements 20 in the first direction DR1 in the emission area EMA. Each of them may have a shape extended in the second direction DR2. It should be understood, however, that the present disclosure is not limited thereto. For example, the shape, size, number, and/or arrangement structure of the first electrode 31 and the second electrode 32 disposed in each of the emission areas EMA may vary depending on the embodiments.

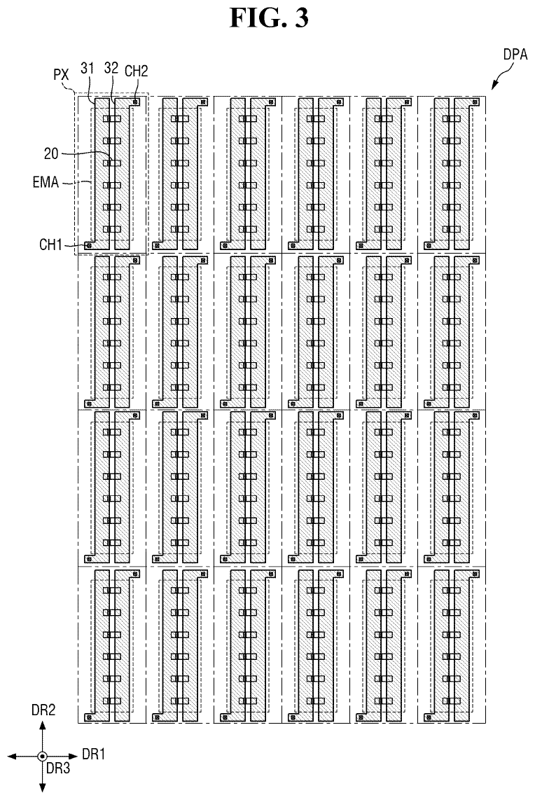

FIG. 3 is a plan view showing a display area DPA of a display device DD according to one or more embodiments of the present disclosure. For example, FIG. 3 is a plan view showing the display area DPA of the display device DD having a higher resolution relative to the embodiment of FIG. 2.

Referring to FIGS. 1-3, the display device DD may be a high-resolution display device including a larger number of pixels PX. For example, a high-resolution display device DD may include a greater number of pixels PX relative to the given area of the display area DPA. The number of light-emitting elements 20 provided to each of the pixels PX (e.g., an appropriate number range) may be constant regardless of the resolution or may vary depending on the resolution.

In the high-resolution display device DD, the emission area EMA of each of the pixels PX may be reduced, and the emission areas EMA of the pixels PX may be more densely arranged. In addition, the sizes of the first electrode 31 and the second electrode 32 provided in each of the emission areas EMA may be reduced. Accordingly, it may be difficult to properly arrange the light-emitting elements 20 during a process of disposing the light-emitting elements 20 in the emission areas EMA of the pixels PX. For example, when the emission areas EMA of the pixels PX are densely arranged and each of the emission areas EMA is reduced, it may be difficult to properly supply a desired number of light-emitting elements 20 to each of the very small emission areas EMA due to the structural limitations of the inkjet printing equipment. If the light-emitting elements 20 are directly transferred to a target substrate (e.g., a backplane substrate of the display device DD) for fabricating a high-resolution display device DD using a separate transfer substrate for each target substrate, it may be difficult to supply and align the light-emitting elements 20 at a target density or concentration to each light-emitting element alignment area of the transfer substrate with a high resolution equal to the resolution of the emission areas EMA of the display device DD. In addition, in order to transfer the light-emitting elements 20 on the transfer substrate to each of the target substrates with a high resolution, it is desirable to accurately align the transfer substrate with each of the target substrates, and accordingly the fabricating process including the alignment process may become very difficult, and the yield of the display device DD may decrease.

One or more embodiments of the present disclosure provide a method and an apparatus for fabricating a display device DD that can overcome such difficulties in the fabrication process and can produce (e.g., easily produce) a high-resolution display device DD. More detailed descriptions thereon will be given later.

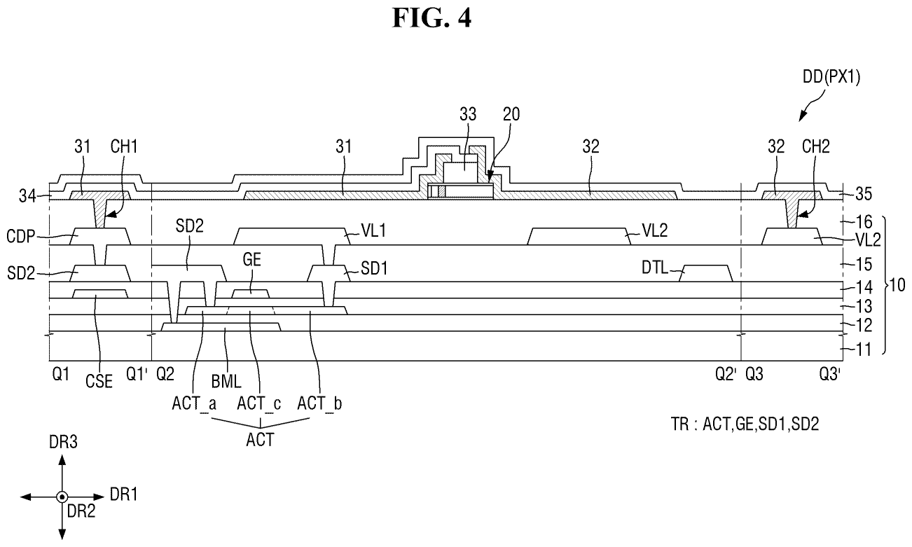

FIG. 4 is a cross-sectional view showing the display device DD according to one or more embodiments of the present disclosure. For example, FIG. 4 shows a cross section of the first pixel PX1, taken along the lines Q1-Q1′, Q2-Q2′ and Q3-Q3′ of FIG. 2. Although FIG. 4 shows only the cross section of one first pixel PX1, the other pixels PX, for example, another first pixel PX1, a second pixel PX2, and a third pixel PX3 may have a cross-sectional structure that is substantially the same as or similar to that of the first pixel PX1 of FIG. 2. In addition, each of the pixels PX according to one or more embodiments of FIG. 3 may also have a cross-sectional structure that is substantially the same as or similar to the first pixel PX1 according to one or more embodiments of FIG. 4. In addition, the cross section of each of the pixels PX is not limited to the embodiment shown in FIG. 4 and the like and may be altered in various ways. In addition, in one or more other embodiments, some pixels PX may have a cross-sectional structure different from that of the other pixels PX.

Referring to FIGS. 1-4, the display device DD may include a base substrate 11, a semiconductor layer disposed on the base substrate 11, a plurality of conductive layers, and a plurality of insulating layers.

The base substrate 11 may be a base member for forming the display panel of the display device DD, and may form a base surface of the display panel. The base substrate 11 may be made of an insulating material such as glass, quartz, and/or a polymer resin. The base substrate 11 may be a rigid substrate and/or a flexible substrate that can be bent, folded, rolled, and/or the like.

A light-blocking layer BML may be disposed on the base substrate 11. The light-blocking layer BML is disposed to overlap with the active layer ACT of at least one transistor TR provided to each of the pixels PX of the display device DD. According to one or more embodiments of the present disclosure, each of the pixels PX may include a pixel circuit including a plurality of transistors TR and at least one capacitor. FIG. 4 shows only one transistor TR as an example of the circuit elements that may be provided to the pixel circuit.

The light-blocking layer BML may include a material that blocks light, and thus can prevent light from entering the active material layer ACT of the transistor TR. For example, the light-blocking layer BML may be formed of an opaque metal material that blocks light transmission. In one or more embodiments, the display device DD may not include the light-blocking layer BML.

A buffer layer 12 may be disposed on the light-blocking layer BML and base substrate 11. For example, the buffer layer 12 may be disposed on the base substrate 11 and may cover the light-blocking layer BML. The buffer layer 12 may include at least one inorganic insulating layer and may protect the pixels PX from permeation of moisture through the base substrate 11 and/or the like. For example, the buffer layer 12 may include silicon oxide (SiOx), silicon nitride (SiNx), and silicon oxynitride (SiOxNy), and/or other inorganic insulating materials.

A semiconductor layer may be disposed on the buffer layer 12. The semiconductor layer may include the active layer ACT of the transistor TR. The active layer ACT may include polycrystalline silicon, monocrystalline silicon, oxide semiconductor, and/or other semiconductor materials. The active layer ACT may include a channel region ACT_c overlapping with a gate electrode GE of the transistor TR, and conductive regions ACT_a and ACT_b located on the both sides of the channel region ACT_c (e.g., source and drain regions), respectively.

A first insulating layer 13 may be disposed on the semiconductor layer and the buffer layer 12. For example, the first insulating layer 13 may be disposed on the buffer layer 12 and may cover patterns provided to the semiconductor layer (e.g., the active layer ACT). According to one or more embodiments of the present disclosure, the first insulating layer 13 may include an inorganic insulating material (e.g., silicon oxide (SiOx), silicon nitride (SiNx), silicon oxynitride (SiOxNy), and/or other inorganic insulating material).

A first conductive layer may be disposed on the first insulating layer 13. The first conductive layer may include the gate electrode GE of the transistor TR and a first capacitor electrode CSE. The gate electrode GE may overlap with the channel region ACT_c of the active layer ACT in the third direction DR3. The first capacitor electrode CSE may be disposed to overlap with the second source/drain electrode SD2 of the transistor TR in the thickness direction (e.g., the third direction DR3) (e.g., see FIG. 4). In one or more other embodiments, the first capacitor electrode CSE may be disposed to overlap with the first source/drain electrode SD1 of the transistor TR in the thickness direction (e.g., the third direction DR3). In one or more embodiments, the first capacitor electrode CSE may be connected to the gate electrode GE. For example, the first capacitor electrode CSE and the gate electrode GE may be integrated as a single pattern. As the first capacitor electrode CSE overlaps with the second source/drain electrode SD2, a capacitor (e.g., a storage capacitor of each of the pixels PX) may be formed between the first capacitor electrode CSE and the second source/drain electrode SD2.

The first conductive layer may be made of at least one conductive material (e.g., molybdenum (Mo), aluminum (Al), chromium (Cr), gold (Au), titanium (Ti), nickel (Ni), neodymium (Nd), and/or copper (Cu), an alloy thereof, and/or other conduct materials). The first conductive layer may be made up of a single layer or multiple layers.

A second insulating layer 14 may be disposed on the first conductive layer and the first insulating layer 13. For example, the second insulating layer 14 may be disposed on the first insulating layer 13, and may cover the patterns of the first conductive layer (e.g., the gate electrode GE of the transistor TR and the first capacitor electrode CSE). According to one or more embodiments of the present disclosure, the second insulating layer 14 may include an inorganic insulating material (e.g., silicon oxide (SiOx), silicon nitride (SiNx), silicon oxynitride (SiOxNy), and/or other inorganic insulating material).

A second conductive layer may be disposed on the second insulating layer 14. The second conductive layer may include a first source/drain electrode SD1 and a second source/drain electrode SD2 of the transistor TR and a data line DTL. The first source/drain electrode SD1 may be one of the source electrode and drain electrode of the transistor TR, and the second source/drain electrode SD2 may be the other one of the source electrode and drain electrode of the transistor TR.

The first source/drain electrode SD1 and the second source/drain electrode SD2 of the transistor TR may be connected to the conductive regions ACT_a and ACT_b of the active layer ACT. For example, the first source/drain electrode SD1 of the transistor TR may be connected to the conductive region ACT_b (e.g., a source region) located on one side of the active layer ACT through a contact hole penetrating the second insulating layer 14 and the first insulating layer 13 (e.g., see FIG. 4). The second source/drain electrode SD2 of the transistor TR may be connected to the conductive region ACT_a (e.g., a drain area) located on the other side of the active layer ACT through another contact hole penetrating the second insulating layer 14 and the first insulating layer 13 (e.g., see FIG. 4). According to one or more embodiments of the present disclosure, the second source/drain electrode SD2 of the transistor TR may be electrically connected to the light-blocking layer BML through a contact hole penetrating through the second insulating layer 14, the first insulating layer 13, and the buffer layer 12.

The data line DTL may apply a data signal to another transistor provided in the pixel PX. In one or more embodiments, the data line DTL may be connected to a source/drain electrode of another transistor.

The second conductive layer may be made of at least one conductive material (e.g., molybdenum (Mo), aluminum (Al), chromium (Cr), gold (Au), titanium (Ti), nickel (Ni), neodymium (Nd), and/or copper (Cu), an alloy thereof, and/or other conduct materials). The second conductive layer may be made up of a single layer or multiple layers.

A third insulating layer 15 may be disposed on the second conductive layer and the second insulating layer 14. For example, the third insulating layer 15 may be disposed on the second insulating layer 14 and cover the second conductive layer. According to one or more embodiments of the present disclosure, the third insulating layer 15 may include an inorganic insulating material (e.g., silicon oxide (SiOx), silicon nitride (SiNx), silicon oxynitride (SiOxNy), and/or other inorganic insulating material).

A third conductive layer may be disposed on the third insulating layer 15. The third conductive layer may include a first voltage line VL1, a second voltage line VL2, and a first conductive pattern CDP. According to one or more embodiments the first voltage line VL1 may be a power line from which a first supply voltage at a high level (e.g., a high-level pixel supply voltage) is applied, and the second voltage line VL2 may be a power line from which a second supply voltage at a low level (e.g., a low-level pixel supply voltage) is applied. According to one or more embodiments of the present disclosure, the first voltage line VL1 may be connected to the first ends of the light-emitting elements 20 via at least one transistor TR, the first electrode 31, etc. provided in each of the pixels PX. The second voltage line VL2 may be connected to the second ends of the light-emitting elements 20 via the second electrode 32, etc. provided in each of the pixels PX.

For example, as shown in FIG. 4, the first conductive pattern CDP may be electrically connected to the second source/drain electrode SD2 of the transistor TR through a contact hole formed in the third insulating layer 15. The first conductive pattern CDP may also be connected to the first electrode 31 though a contact hole CH1 penetrating a fourth insulating layer 16. The second electrode 32 may be connected to the second voltage line VL2 though a contact hole CH2 penetrating the fourth insulating layer 16. The first voltage line VL1 may be connected to the first source/drain electrode SD1 of the transistor TR via a contact hole penetrating the third insulating layer 15. The transistor TR may transfer the first supply voltage applied from the first voltage line VL1 to the first electrode 31 through the first conductive pattern CDP. According to one or more embodiments, at least a part of the first electrode 31 may overlap with the first voltage line VL1 in the third direction DR3. Although the third conductive layer includes one second voltage line VL2 and one first voltage line VL1 in the example shown in FIG. 4, the present disclosure is not limited thereto. For example, the third conductive layer may include more than one first voltage lines VL1 and second voltage lines VL2.

The third conductive layer may be made of at least one conductive material (e.g., molybdenum (Mo), aluminum (Al), chromium (Cr), gold (Au), titanium (Ti), nickel (Ni), neodymium (Nd), and/or copper (Cu), an alloy thereof, and/or other conduct materials). The third conductive layer may be made up of a single layer or multiple layers.

A fourth insulating layer 16 (e.g., a planarization layer) may be disposed on the third conductive layer and the third insulating layer 15. The fourth insulating layer 16 may include an organic insulating material (e.g., polyimide (PI) or other organic insulating materials). The surface of the fourth insulating layer 16 may be substantially flat.

The elements from the base substrate 11 to the fourth insulating layer 16 may form a lower substrate 10 of the display device DD (e.g., a backplane substrate of the display panel). The light-emitting elements 20, and the first electrode 31 and the second electrode 32 connected to the light-emitting elements 20 may be disposed on the fourth insulating layer 16. In addition, a plurality of insulating layers 33, 34, and 35 may be further disposed on the fourth insulating layer 16.

The light-emitting elements 20 may be disposed on the lower substrate 10. For example, the light-emitting elements 20 may be disposed on the fourth insulating layer 16. According to one or more embodiments of the present disclosure, the light-emitting elements 20 may be disposed directly on the fourth insulating layer 16, but the present disclosure is not limited thereto.

According to one or more embodiments of the present disclosure, a plurality of light-emitting elements 20 may be disposed on the fourth insulating layer 16 in the emission area EMA of each of the pixels PX. For example, the light-emitting elements 20 may be arranged along the second direction DR2 and may be aligned substantially parallel to one another. According to one or more embodiments of the present disclosure, each of the light-emitting elements 20 may have a shape extended in a direction (e.g., the first direction DR1). The direction in which the first electrode 31 and the second electrode 32 are extended may be substantially perpendicular to the direction in which the light-emitting elements 20 are extended. It should be noted that the present disclosure is not limited thereto. At least one light-emitting element 20 may be oriented obliquely to the direction in which the first electrode 31 and the second electrode 32 are extended rather than being perpendicular to the direction.

Each of the light-emitting elements 20 may include first and second semiconductor layers (e.g., p-type and n-type semiconductor layers), and an emissive layer disposed between the first and second semiconductor layers to generate light in a certain wavelength range. According to one or more embodiments of the present disclosure, the light-emitting element 20 may further include at least one electrode layer located at at least one end. According to one or more embodiments, the light-emitting element 20 may have a size in micrometers or nanometers and may be a light-emitting diode made of an inorganic material, but the present disclosure is not limited thereto.

According to one or more embodiments of the present disclosure, a fifth insulating layer 33 (or insulating pattern) may be disposed on a part of the light-emitting elements 20. For example, the fifth insulating layer 33 may be disposed on a portion including the central portion of each of the light-emitting elements 20 but not on the other portions including the both ends of each of the light-emitting elements 20 (e.g., the both ends in the longitudinal direction). Accordingly, the both ends of each of the light-emitting elements 20 may be exposed without being covered by the fifth insulating layer 33. The fifth insulating layer 33 can protect the light-emitting elements 20 and fix the light-emitting elements 20 at the aligned and/or disposed positions during the process of fabricating the display device DD.

The first electrode 31 and the second electrode 32 may be disposed on the both ends of each of the light-emitting elements 20, respectively. For example, the first electrode 31 may be disposed on an end (e.g., P-type end) of each of the light-emitting elements 20, and the second electrode 32 may be disposed on the other end (e.g., N-type end) of each of the light-emitting elements 20. The first electrode 31 and the second electrode 32 may be electrically connected to the light-emitting elements 20 disposed in the respective emission areas EMA. Electrical signals may be applied to the light-emitting elements 20 through the first electrode 31 and the second electrode 32.

According to one or more embodiments of the present disclosure, the first electrode 31 and the second electrode 32 may be sequentially formed on the base substrate 11, and a sixth insulating layer 34 may be formed between the first electrode 31 and the second electrode 32. The display device DD may further include a seventh insulating layer 35 that is disposed entirely in the display area DA, etc., and covers the light-emitting elements 20, the first electrode 31, the second electrode 32, the fifth insulating layer 33, and the sixth insulating layer 34.

The first electrode 31 may be disposed on the fourth insulating layer 16 and may cover the first ends of the light-emitting elements 20 disposed in each of the emission areas EMA. As an example, the first electrode 31 may be disposed on the first ends of the light-emitting elements 20 to be in contact with the first ends of the light-emitting elements 20, and accordingly, it can be electrically connected to the first ends of the light-emitting elements 20. According to one or more embodiments of the present disclosure, an end of the first electrode 31 may be disposed directly on the fifth insulating layer 33. The first electrode 31 may be a single-layer or multi-layer electrode containing at least one conductive material. According to one or more embodiments of the present disclosure, the first electrode 31 may be a transparent electrode containing a transparent conductive material (e.g., indium tin oxide (ITO), indium zinc oxide (IZO), indium tin-zinc oxide (ITZO), and/or other transparent conductive materials). Accordingly, light emitted from the light-emitting elements 20 may pass through the first electrodes 31. According to one or more embodiments of the present disclosure, the first electrode 31 may be a reflective electrode including a highly reflective conductive material (e.g., silver (Ag), copper (Cu), aluminum (Al), and/or other reflective metals). Accordingly, the emission efficiency of the pixels PX can be increased. The material, structure, shape, etc. of the first electrode 31 may vary depending on the embodiments.

According to one or more embodiments of the present disclosure, the first electrode 31 may be electrically connected to at least one transistor TR provided in each of the pixels PX through a first contact hole CH1. For example, the first electrode 31 may be in contact with the first conductive pattern CDP through the first contact hole CH1 penetrating the fourth insulating layer 16, and may be electrically connected to at least one transistor TR provided in that pixel PX through the first conductive pattern CDP.

The sixth insulating layer 34 may be disposed on the first electrode 31. For example, the sixth insulating layer 34 may be disposed on the fourth insulating layer 16 and cover the first electrode 31 and the fifth insulating layer 33. The sixth insulating layer 34 may not be disposed on the second ends of the light-emitting elements 20.

The second electrode 32 may be disposed on the fourth insulating layer 16 and may cover the second ends of the light-emitting elements 20 disposed in each of the emission areas EMA. As an example, the first electrode 31 may be disposed on the second ends of the light-emitting elements 20 to be in contact with the second ends of the light-emitting elements 20, and accordingly, it can be electrically connected to the second ends of the light-emitting elements 20. According to one or more embodiments of the present disclosure, one end of the second electrode 32 may be disposed directly on the fifth insulating layer 33 and/or the sixth insulating layer 34. The second electrode 32 may be a single-layer or multi-layer electrode containing at least one conductive material. According to one or more embodiments of the present disclosure, the second electrode 32 may be a transparent electrode containing a transparent conductive material, and thus lights emitted from the light-emitting elements 20 may pass through the second electrode 32. According to one or more embodiments of the present disclosure, the second electrode 32 may be a reflective electrode containing a highly reflective conductive material. Accordingly, the emission efficiency of the pixels PX can be increased. The material, structure, shape, etc. of the second electrode 32 may vary depending on the embodiments.

According to one or more embodiments of the present disclosure, the second electrode 32 may be electrically connected to the second voltage line VL2 through the second contact hole CH2. For example, the second electrode 32 may be in contact with the second voltage line VL2 through the second contact hole CH2 penetrating the fourth insulating layer 16.

The seventh insulating layer 35 may be disposed on the second electrode 32. For example, the seventh insulating layer 35 may be disposed on the fourth insulating layer 16, and may be formed entirely on a surface of the base substrate 11 to cover the first electrode 31, the second electrode 32, the fifth insulating layer 33, the sixth insulating layer 34, etc.

Each of the fifth insulating layer 33, the sixth insulating layer 34, and the seventh insulating layer 35 may be a single-layer or multi-layer insulating layer including an inorganic insulating material and/or an organic insulating material. For example, each of the fifth insulating layer 33, the sixth insulating layer 34 and the seventh insulating layer 35 may include: silicon oxide (SiOx), silicon nitride (SiNx), silicon oxynitride (SiOxNy), aluminum oxide (Al2O3), aluminum nitride (AlN), and/or other inorganic insulating materials, and/or an acrylic resin, an epoxy resin, a phenol resin, a polyamide resin, a polyimide resin, an unsaturated polyester resin, a polyphenylene resin, a polyphenylene sulfide resin, benzocyclobutene, a cardo resin, a siloxane resin, a silsesquioxane resin, a polymethyl methacrylate, polycarbonate, a polymethyl methacrylate-polycarbonate synthetic resin, and/or other organic insulating materials.

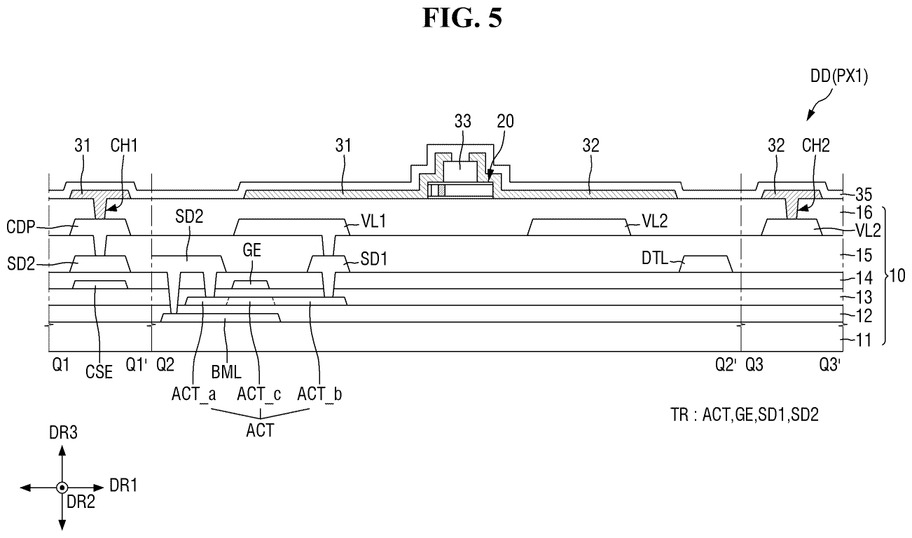

FIG. 5 is a cross-sectional view showing the display device DD according to one or more embodiments of the present disclosure. For example, FIG. 5 shows an embodiment different from the embodiment of FIG. 4 with respect to the cross section of the first pixel PX1 along the lines Q1-Q1′, Q2-Q2′, and Q3-Q3′ of FIG. 2.

Referring to FIG. 5 in conjunction with FIGS. 1-4, the display device DD may not include the sixth insulating layer 34 of FIG. 4. For example, the first electrode 31 and the second electrode 32 may be disposed in the same layer (e.g., at the same layer) on the base substrate 11 and may be formed concurrently (e.g., simultaneously) or sequentially. The first electrode 31 and the second electrode 32 may be spaced from each other with the fifth insulating layer 33 interposed therebetween and may be covered with the seventh insulating layer 35. According to one or more embodiments of the present disclosure, an end of the second electrode 32 may be disposed directly on the fifth insulating layer 33.

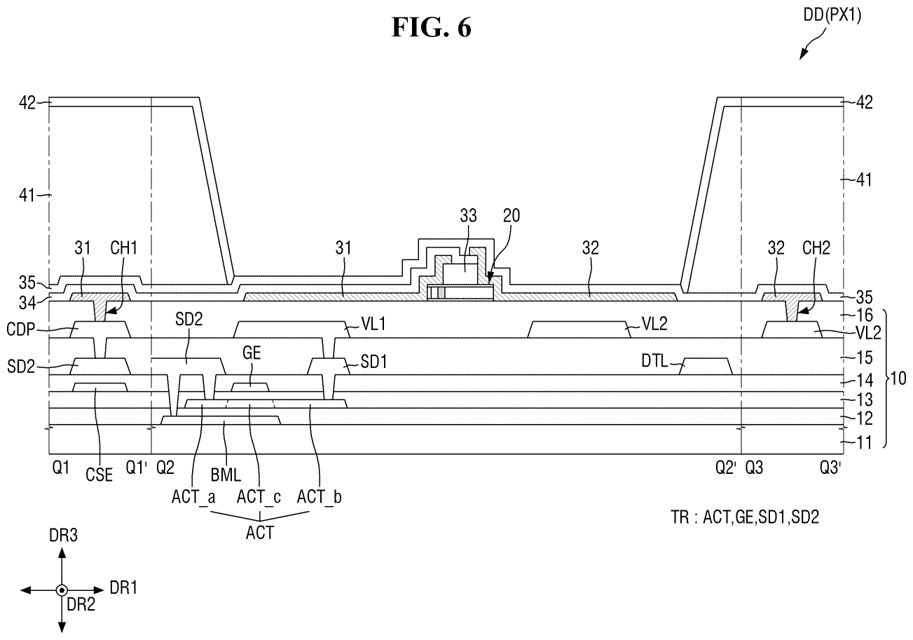

FIG. 6 is a cross-sectional view showing the display device DD according to one or more embodiments of the present disclosure. For example, FIG. 6 shows an embodiment different from the embodiment of FIG. 4 with respect to the cross section of the first pixel PX1 along the lines Q1-Q1′, Q2-Q2′, and Q3-Q3′ of FIG. 2.

Referring to FIG. 6 in conjunction with FIGS. 1-5, a display device DD may further include a bank 41 disposed on the seventh insulating layer 35. According to one or more embodiments of the present disclosure, the bank 41 may be around (e.g., may surround) the emission area EMA of each pixel PX. For example, the bank 41 may be implemented as a plurality of insulating patterns each extended in the second direction DR2 and disposed on the both sides of the emission area EMA (e.g., a pair of insulating patterns spaced from each other in the first direction DR1), or may be an insulating pattern that has openings associated with the emission areas EMA of the pixels PX and is disposed in the display area DA such that it surrounds the emission areas EMA on the four sides (e.g., a mesh-like insulating pattern). According to one or more embodiments of the present disclosure, the bank 41 may include at least one organic insulating layer containing an organic insulating material. According to one or more embodiments of the present disclosure, the bank 41 may include inclined surfaces that are inclined at a certain angle or have a gently curved shape. At least some of the lights emitted from the light-emitting elements 20 may travel toward the inclined side surfaces of the bank 41.

According to one or more embodiments of the present disclosure, the display device DD may further include a reflective pattern layer 42 disposed on the bank 41. As an example, the display device DD may include a reflective pattern layer 42 disposed on the side surfaces and/or upper surface of the bank 41.

The reflective pattern layer 42 may include a highly reflective material (e.g., a highly reflective metal). Reflective partition walls may be formed on the outer side of the emission areas EMA by the bank 41 and the reflective pattern layer 42. Accordingly, the emission efficiency of the pixels PX can be increased.

Although FIG. 6 shows only a modification of the embodiment of FIG. 4, the embodiment of FIG. 6 may also be applied to the embodiment of FIG. 5. For example, as shown in FIG. 6, the bank 41 and/or the reflective pattern layer 42 may be disposed even in the display device DD that does not include the sixth insulating layer 34.

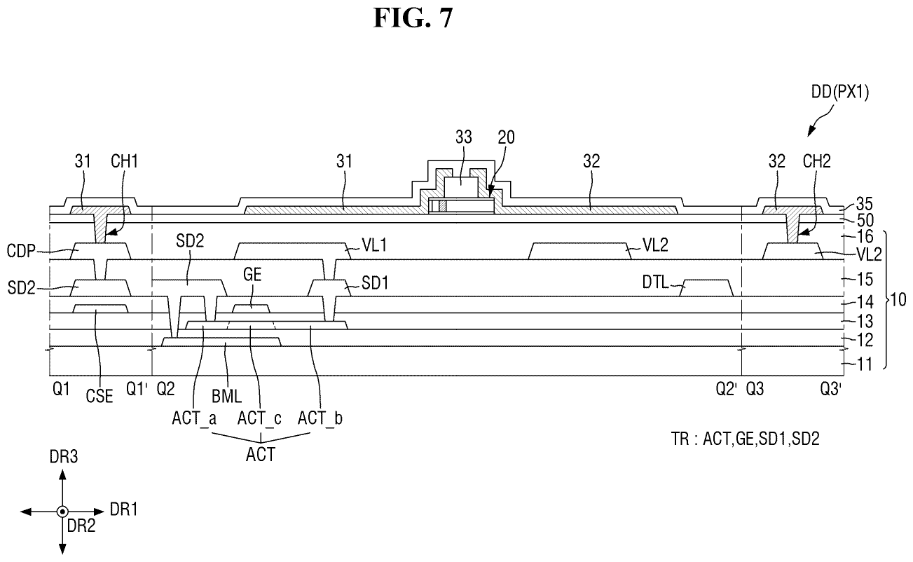

FIG. 7 is a cross-sectional view showing a display device DD according to one or more embodiments of the present disclosure. For example, FIG. 7 shows an embodiment different from the embodiment of FIG. 5 with respect to the cross section of the first pixel PX1 taken along the lines Q1-Q1′, Q2-Q2′ and Q3-Q3′ of FIG. 2. Although FIG. 7 shows only a modification of the embodiment of FIG. 5, the embodiment of FIG. 7 may also be applied to the embodiment of FIG. 4 and/or the embodiment of FIG. 6.

Referring to FIG. 7 in conjunction with FIGS. 1-6, the display device DD may further include an adhesive layer 50. The adhesive layer 50 may be disposed on the fourth insulating layer 16. Light-emitting elements 20, a first electrode 31, a second electrode 32, etc. may be disposed on the adhesive layer 50. In the process of fabricating the display device DD, a first contact hole CH1 and a second contact hole CH2 may be formed after the adhesive layer 50 has been formed. For example, the first contact hole CH1 and the second contact hole CH2 may penetrate the adhesive layer 50. The adhesive layer 50 may be made of, but is not limited to, a material including an epoxy-based polymer such as SU-8, benzocyclobutene (BCB), polyimide (PI), polybenzoxazole (PBO), silicone (Si), and/or heat release coating. By disposing the adhesive layer 50 on the fourth insulating layer 16, the light-emitting elements 20 may be stably disposed on a lower substrate 10 of the display device DD.

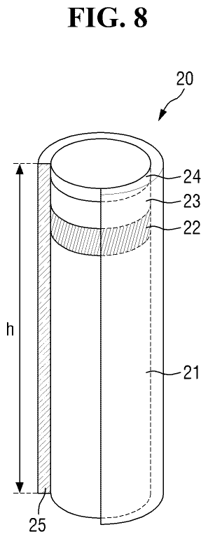

FIG. 8 is a perspective cutaway view showing a light-emitting element 20 according to one or more embodiments.

Referring to FIG. 8, the light-emitting element 20 may be a light-emitting diode. According to one or more embodiments of the present disclosure, the light-emitting element 20 may have size in micrometers or nanometers and may be an inorganic light-emitting diode made of an inorganic material.

The light-emitting element 20 may include a first semiconductor layer 21, an emissive layer 22 (also referred to as “active layer” of the light-emitting element 20) and a second semiconductor layer 23, which are sequentially arranged and/or stacked along one direction (e.g., longitudinal direction or height direction). According to one or more embodiments of the present disclosure, the light-emitting element 20 may further include an electrode layer 24 disposed on the second semiconductor layer 23. For example, the electrode layer 24 may be located at a first end (e.g., P-type end) of the light-emitting element, and the first semiconductor layer 21 may be located at a second end (e.g., N-type end) of the light-emitting element. In one or more embodiments, the light-emitting element 20 may further include an additional electrode layer. As an example, the light-emitting element 20 may further include an electrode layer located at the second end. The shape, structure and/or size of the light-emitting element 20 may vary depending on embodiments.

The light-emitting element 20 may further include an insulating film 25 around (e.g., surrounding) at least the emissive layer 22 and at least a part of the first semiconductor layer 21 and the second semiconductor layer 23. For example, the insulating film 25 may be around (e.g., may surround) outer peripheral or circumferential surfaces of at least the emissive layer 22 and at least a part of the first semiconductor layer 21 and the second semiconductor layer 23. According to one or more embodiments of the present disclosure, the insulating film 25 may be further around (may further surround) at least a part of the electrode layer 24. The insulating film 25 may expose the both ends of the light-emitting element 20.

The first semiconductor layer 21 may include a semiconductor of a first conductivity type including a dopant of the first conductivity type. For example, the first semiconductor layer 21 may be an N-type semiconductor layer containing an N-type dopant.

According to one or more embodiments of the present disclosure, the first semiconductor layer 21 may include a nitride semiconductor material or a phosphide semiconductor material. For example, the first semiconductor layer 21 may include a nitride semiconductor material including GaN, AlGaN, InGaN, AlInGaN, AlN, and/or InN, or a phosphide semiconductor material including GaP, GaInP, AlGaP, AlGaInP, AlP, and/or InP. The first semiconductor layer 21 may include other materials. According to one or more embodiments of the present disclosure, the first semiconductor layer 21 may include an N-type dopant such as Si, Ge, and/or Sn. The first semiconductor layer 21 may include other dopants.

The emissive layer 22 may be disposed on the first semiconductor layer 21. The emissive layer 22 may include a single or multiple quantum well structure. When a voltage higher than the threshold voltage is applied to the both ends of the light-emitting element 20, electron-hole pairs may recombine in the emissive layer 22. In this manner, light can be emitted from the light-emitting element 20.

According to one or more embodiments of the present disclosure, the emissive layer 22 may emit light in a visible wavelength range, for example, light in a wavelength range of approximately 400 nm to 900 nm. For example, the emissive layer 22 may emit blue light with a peak wavelength ranging from approximately 440 nm to 480 nm, green light with a peak wavelength ranging from approximately 510 nm to 550 nm, or red light with a peak wavelength ranging from approximately 610 nm to 650 nm. The emissive layer 22 may emit light in other colors and/or wavelength ranges in addition to the colors and/or wavelength ranges mentioned above.

According to one or more embodiments of the present disclosure, the emissive layer 22 may include a nitride semiconductor material and/or a phosphide semiconductor material. For example, the emissive layer 22 may include a nitride semiconductor material including GaN, AlGaN, InGaN, InGaAlN, AlN, and/or InN, and/or a phosphide semiconductor material including GaP, GaInP, AlGaP, AlGaInP, AlP, and/or InP. The emissive layer 22 may include other suitable materials known to a person having ordinary skill in the art.

The second semiconductor layer 23 may be disposed on the emissive layer 22. The second semiconductor layer 23 may include a semiconductor layer of a second conductivity type that includes a dopant of the second conductivity type. For example, the second semiconductor layer 23 may be a P-type semiconductor layer including a P-type dopant.

According to one or more embodiments of the present disclosure, the second semiconductor layer 23 may include a nitride semiconductor material and/or a phosphide semiconductor material. For example, the second semiconductor layer 23 may include a nitride semiconductor material including GaN, AlGaN, InGaN, AlInGaN, AlN, and/or InN, and/or a phosphide semiconductor material including GaP, GaInP, AlGaP, AlGaInP, AlP, and/or InP. The second semiconductor layer 23 may include other materials. According to one or more embodiments of the present disclosure, the second semiconductor layer 23 may include a P-type dopant such as Mg. The second semiconductor layer 23 may include other dopants.

According to one or more embodiments of the present disclosure, the first semiconductor layer 21 and the second semiconductor layer 23 may have different lengths (or thicknesses) in the longitudinal direction of the light-emitting element 20. For example, the first semiconductor layer 21 may have a greater length (or a greater thickness) than the second semiconductor layer 23 along the longitudinal direction of the light-emitting element 20.

The electrode layer 24 may be disposed on the second semiconductor layer 23. The electrode layer 24 may protect the second semiconductor layer 23 and smoothly connect the second semiconductor layer 23 with at least one circuit element, electrode, and/or line. For example, the electrode layer 24 may be an ohmic contact electrode or a Schottky contact electrode.

According to one or more embodiments of the present disclosure, the electrode layer 24 may include metal and/or metal oxide. For example, the electrode layer 24 may include metals such as chromium (Cr), titanium (Ti), aluminum (Al), gold (Au), nickel (Ni) and copper (Cu), oxides, and/or alloys thereof, and/or transparent conductive materials such as indium tin oxide (ITO), indium zinc oxide (IZO), indium tin zinc oxide (ITZO), Zinc Oxide (ZnO), and/or indium oxide (In₂O₃). Alternatively, the electrode layer 24 may include a semiconductor material doped into

P-type or N-type dopant. According to one or more embodiments of the present disclosure, the electrode layer 24 can be substantially transparent. Accordingly, light generated by the light-emitting element 20 can be transmitted through the electrode layer 24.

The insulating film 25 may be disposed to be around (e.g., to surround) at least the outer surface (e.g., the outer peripheral or circumferential surface) of the emissive layer 22. According to one or more embodiments of the present disclosure, the insulating film 25 may be extended in the direction in which the light-emitting device 20 is extended, and may be around (e.g., may surround) the outer surfaces (e.g., side surfaces or the outer peripheral or circumferential surfaces) of the first semiconductor layer 21, the emissive layer 22, the second semiconductor layer 23 and/or the electrode layer 24. The insulating film 25 may include silicon oxide (SiOx), silicon nitride (SiNx), silicon oxynitride (SiOxNy), aluminum oxide (Al₂O₃), aluminum nitride (AlN), and/or other insulating materials. The insulating film 25 can prevent the emissive layer 22 from being in direct contact with the first electrode 31 and/or the second electrode 32 and can protect the outer surface (e.g., the outer peripheral or circumferential surface) of the light-emitting element 20.

According to one or more embodiments of the present disclosure, the length h of the light-emitting element 20 may range from approximately 1 μm to 10μm or 2 μm to 6 μm. For example, the length h of the light-emitting element 20 may range from 3 μm to 5 μm. According to one or more embodiments of the present disclosure, the diameter (or width of the cross section) of the light-emitting element 20 may range from 30 nm to 700 nm, and the aspect ratio of the light-emitting element 20 may range from 1.2 to 100. For example, the light-emitting element 20 may have a rod shape extended in a direction. The shape or size of the light-emitting element 20 is not particularly limited, and may vary depending on embodiments.

In one or more embodiments, the display device DD may include light-emitting elements 20 disposed directly on the fourth insulating layer 16 or the adhesive layer 50. In addition, the display device DD may not include separate alignment electrodes to which an alignment signal for aligning the light-emitting elements 20 is applied.

If the display device DD includes separate alignment electrodes and an alignment signal is applied to the alignment electrodes to align the light-emitting elements 20 in each of the emission areas EMA, the voltage applied to the alignment electrodes may cause damage to the lines and/or electrodes included in the lower substrate 10. In addition, the alignment electrodes may form an electric field along with the lines and/or electrodes included in the lower substrate 10 to align the light-emitting elements 20 at undesirable positions. In contrast, according to one or more embodiments of the present disclosure, no alignment electrode is formed on the lower substrate 10 of the display device DD, so that it is possible to reduce damage to the lines included in the lower substrate 10, and to improve the alignment of the light-emitting elements 20.

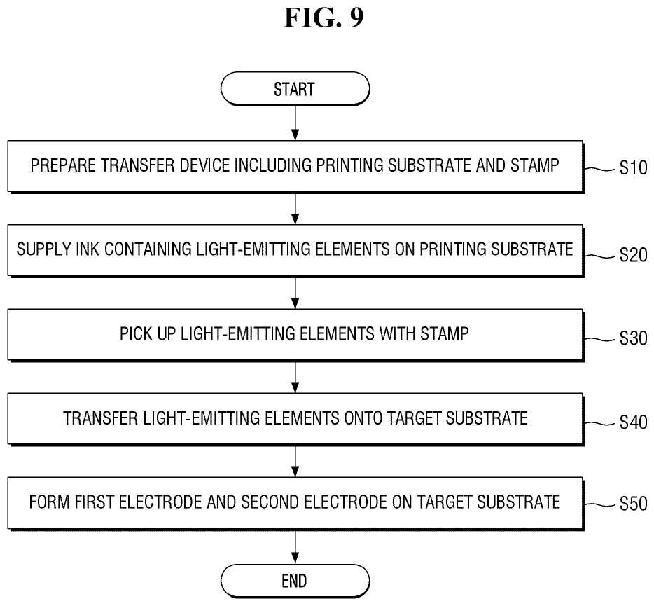

FIG. 9 is a flowchart for illustrating a method of fabricating a display device DD according to one or more embodiments of the present disclosure.

Referring to FIG. 9 in conjunction with FIGS. 1-8, a method of fabricating a display device DD according to one or more embodiments may include: preparing a transfer device including a printing substrate and a stamp (step S10); supplying an ink containing light-emitting elements 20 on the printing substrate (step S20); picking up the light-emitting elements 20 with a stamp (step S30); transferring the light-emitting elements 20 to a target substrate (step S40); and forming a first electrode 31 and a second electrode 32 on the target substrate (step S50). For example, the method according to the embodiment of FIG. 9 may include disposing the light-emitting elements 20 on the lower substrate 10 of the display device DD using the transfer device including the printing substrate and the stamp, and performing a subsequent pixel process.

According to one or more embodiments of the present disclosure, the transfer device may include alignment electrodes provided on a printing substrate and/or a stamp, and a capping layer covering the alignment electrodes. The method of fabricating a display device DD using the transfer device may further include aligning the light emitting elements 20 on the printing substrate and/or the stamp by applying an alignment signal to alignment electrodes provided on the printing substrate or the stamp. In addition, the method of fabricating the display device DD using the transfer device may further include aligning the light-emitting elements 20 on the printing substrate and/or the stamp, and then drying the ink so that the light-emitting elements 20 are fixed as they are aligned.

In the following description, the lower substrate 10 of the display device DD on which the light-emitting elements 20 are to be transferred may also be referred to as a “target substrate.” In addition, in the following description, fabrication devices for the display device DD used to transfer the light-emitting elements 20 to the target substrate 10, including the printing substrate and the stamp, will be described as the elements included in the transfer device. It should be understood, however, that the present disclosure is not limited thereto. For example, the printing substrate and the stamp are separate devices for fabricating the display device DD, and may be used in combination to fabricate the display device DD. The structures of the printing substrate and the stamp and the method of fabricating the display device DD using them according to one or more embodiments will be described in more detail below.

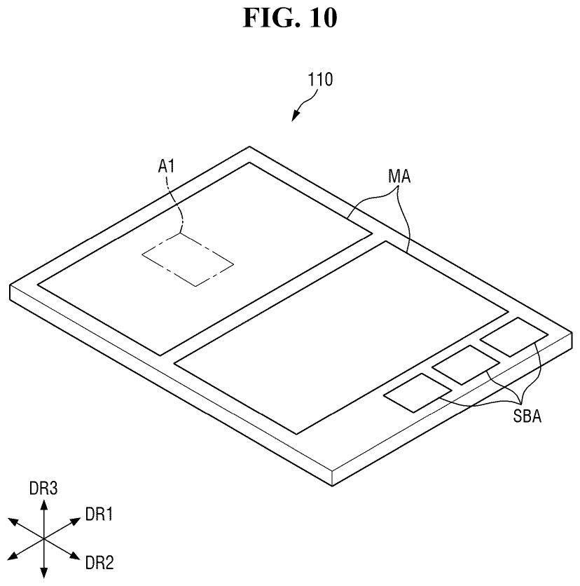

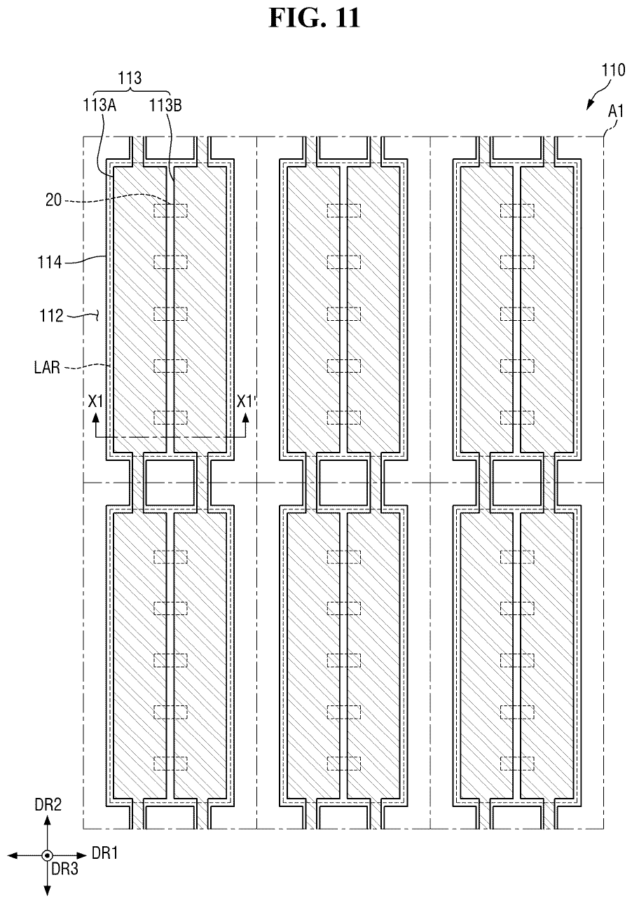

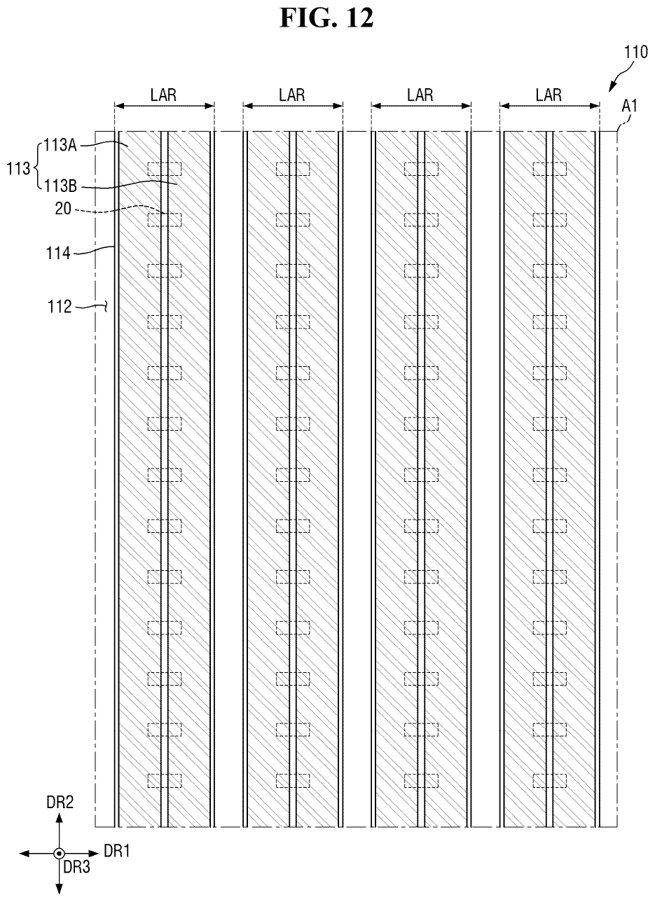

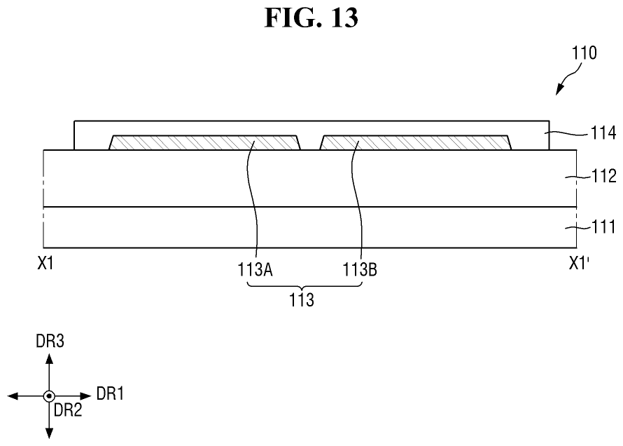

FIG. 10 is a perspective view schematically showing a printing substrate 110 according to one or more embodiments. FIG. 11 is a plan view showing the printing substrate 110 according to the embodiment of the present disclosure. FIG. 12 is a plan view showing a printing substrate 110 according to one or more embodiments of the present disclosure. For example, FIGS. 11 and 12 show a portion of the printing substrate 110 corresponding to an area A1 of FIG. 10. The embodiment of FIG. 11 is different from the embodiment of FIG. 12 with respect to the patterns provided on the printing substrate 110. FIG. 13 is a cross-sectional view showing a printing substrate 110 according to one or more embodiments of the present disclosure. For example, FIG. 13 shows a cross-section of the printing substrate 110 taken along the line X1-X1′ of FIG. 11.

Referring to FIGS. 10-13 in conjunction with FIGS. 1-9, the printing substrate 110 according to one or more embodiments may include at least one main area MA and at least one subsidiary area SBA. Although the printing substrate 110 includes two main areas MA and three subsidiary areas SBA according to the embodiment shown in FIG. 10, the number and size of the main areas MA and the subsidiary areas SBA of the printing substrate 110 may be altered in various ways. In addition, in one or more embodiments, the printing substrate 110 may not include a separate sub-area SBA.

Each of the main areas MA and the subsidiary areas SBA may include at least one light-emitting element supply area LAR. For example, the main areas MA may include a plurality of light-emitting element supply areas LAR, and each of the light-emitting element supply areas LAR located in the main areas MA may include an area where light-emitting elements 20 to be transferred to at least one pixel PX are supplied/aligned. The subsidiary areas SBA may be areas where the light-emitting elements 20 for repair are additionally supplied and/or aligned, and may have a smaller area than the main areas MA. For example, the subsidiary areas SBA may include smaller and/or less light-emitting element supply areas LAR than the main areas MA. A smaller number of light-emitting elements 20 may be supplied and/or aligned in the subsidiary areas than in the main areas MA.

According to one or more embodiments, the printing substrate 110 may include alignment electrodes 113 and a capping layer 114 covering the alignment electrodes 113. For example, the printing substrate 110 may include a support substrate 111, a bank 112 disposed entirely on the support substrate 111, alignment electrodes 113 disposed on the bank 112, and a capping layer 114 covering the alignment electrodes 113. According to one or more embodiments of the present disclosure, the printing substrate 110 may include a dam-shaped structure located at the border, or the bank 112 may be exposed at the border of the printing substrate 110. Accordingly, it is possible to prevent the ink supplied on the printing substrate 110 from overflowing.

Each of the main areas MA and the subsidiary areas SBA may include at least one pair of alignment electrodes 113 and a capping layer 114 covering the alignment electrodes 113. For example, in the light-emitting element supply area LAR of each of the main areas MA and the subsidiary areas SBA, a pair of a first alignment electrode 113A and a second alignment electrode 113B adjacent to each other, and the capping layer 114 covering the first alignment electrode 113A and the second alignment electrode 113B may be disposed.

According to one or more embodiments of the present disclosure, the main areas MA may include a plurality of light-emitting element supply areas LAR associated with the plurality of pixels PX formed on the target substrate 10, respectively. For example, the main areas MA may include a plurality of light-emitting element supply areas LAR arranged along the first direction DR1 and the second direction DR2 as shown in FIG. 11, and the plurality of light-emitting element supply areas LAR may correspond to the emission areas EMA of the pixels PX arranged along the first direction DR1 and the second direction DR2 in the display area DPA of the target substrate 10. As an example, the plurality of light-emitting element supply areas LAR shown in FIG. 11 may be arranged with the resolution, size, and/or spacing equal to or corresponding to those of the emission areas EMA of the first pixels PX1, the second pixels PX2, and the third pixels PX3 forming the first and second unit pixels UPX1 and UPX2 shown in FIG. 2. The alignment electrodes 113 provided on the printing substrate 110 may have a size and/or shape depending on the locations where the light-emitting elements 20 are to be arranged. For example, a pair of first alignment electrodes 113A and a second alignment electrode 113B may be disposed in each of the light-emitting element supply area LAR, and the pair of first alignment electrodes 113A and the second alignment electrodes 113B may be arranged close to each other at positions where the light-emitting elements 20 are to be supplied and aligned.

Alternatively, each of the plurality of light-emitting element supply areas LAR located in the main areas MA may correspond to the emission areas EMA of the plurality of pixels PX formed on the target substrate 10. For example, the main areas MA may include a plurality of light-emitting element supply areas LAR arranged along the first direction DR1 and extended the second direction DR2 as shown in FIG. 12, and the plurality of light-emitting element supply areas LAR may be associated with the emission areas EMA of the pixels PX arranged along the first direction DR1 and the second direction DR2 in the display area DPA of the target substrate 10. As an example, each of the plurality of light-emitting element supply areas LAR shown in FIG. 12 may correspond to the emission areas EMA of at least two pixels PX arranged contiguously in one column of the display area DPA along the second direction DR2 in FIG. 2 or 3. In addition, in the first direction DR1, the plurality of light-emitting element supply areas LAR shown in FIG. 12 may be arranged with the resolution, size and/or spacing equal to or corresponding to those of the emission areas EMA of the pixels PX of the target substrate 10, or may be arranged with the resolution, size and/or spacing different from the resolution of the pixels PX.

The support substrate 111 may be, but is not limited to, an insulating substrate made of an insulating material such as glass, quartz and polymer resin. For example, the support substrate 111 may be made of: molybdenum (Mo), aluminum (Al), chromium (Cr), gold (Au), titanium (Ti), nickel (Ni), neodymium (Nd), and/or copper (Cu), and/or an alloy thereof. In addition, the support substrate 111 may be a rigid or flexible substrate.

The bank 112 may be disposed entirely on the support substrate 111. A part of the bank 112 may be covered with the alignment electrodes 113 and/or the capping layer 114, and another part of the bank 112 may not be covered with the alignment electrodes 113 or the capping layer 114 but may be exposed. For example, a pair of a first alignment electrode 113A and a second alignment electrode 113B and the capping layer 114 covering the pair of first alignment electrode 113A and the second alignment electrode 113B may be placed only on a part of the bank 112 and expose the other part of the bank 112.

According to one or more embodiments of the present disclosure, the bank 112 may be a liquid-repellent bank. For example, the surface (e.g., top surface) of the bank 112 may have liquid-repellency. Liquid repellency may refer to the properties of repelling an ink when the ink containing light-emitting elements 20 is supplied (e.g., dropped or applied) onto the printing substrate 110 by inkjet printing and/or the like. According to one or more embodiments of the present disclosure, the bank 112 may be formed of an organic film containing a liquid-repellent organic material, or may be formed to have liquid-repellency by surface treatment (e.g., water-repellent treatment).

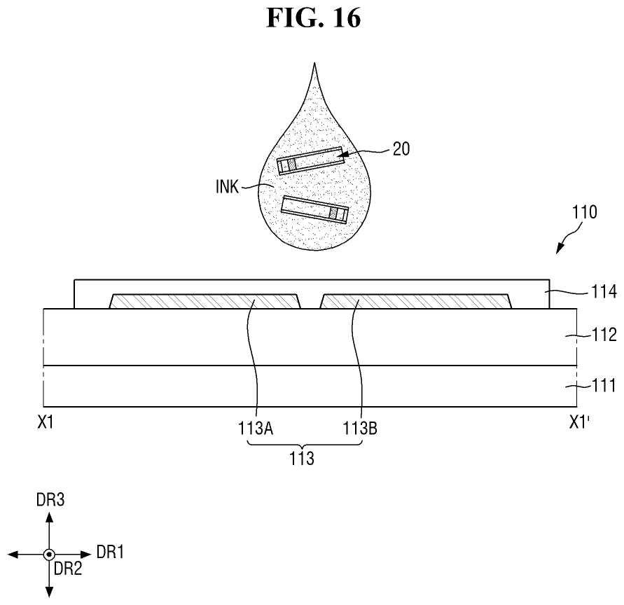

When the ink containing the light-emitting elements 20 is supplied on the exposed portions of the liquid-repellent bank 112 (e.g., between and/or around the light-emitting element supply areas LAR), the bank 112 can push the ink to the nearby light-emitting element supply areas LAR. For example, the bank 112 may be, but is not limited to, a liquid-repellent bank with a contact angle of approximately 60° or more (e.g., a contact angle of approximately 60° to 130° when the ink containing the light-emitting elements 20 is dropped on the surface. By disposing the liquid-repellent bank 112 on the printing substrate 110, the efficiency of using the ink INK (e.g., see FIG. 16) can be increased and the fabrication costs can be saved.

The alignment electrodes 113 may be arranged along the first direction DR1, and each may be extended in the second direction DR2. The alignment electrodes 113 may include a first alignment electrode 113A and a second alignment electrode 113B disposed in each of the light-emitting element supply areas LAR. For example, the first alignment electrode 113A and the second alignment electrode 113B adjacent to each other may be disposed in each of the light-emitting element supply areas LAR defined in the main area MA and the subsidiary area SBA. According to one or more embodiments of the present disclosure, the first alignment electrode 113A and the second alignment electrode 113B located in each light-emitting element supply area LAR may be spaced from each other in the first direction DR1. Each of the alignment electrodes 113 may contain at least one conductive material and may have a single-layer or multi-layer structure. The materials and/or structures of the alignment electrodes 113 may vary in a variety of ways.

According to one or more embodiments of the present disclosure, the first alignment electrode 113A and the second alignment electrode 113B may be used to form an electric field in order to align the light-emitting elements 20 over the printing substrate 110. For example, the light-emitting elements 20 supplied to each of the light-emitting element supply area LAR may be disposed and/or aligned between the first alignment electrode 113A and the second alignment electrode 113B by the electric field formed by the alignment signal applied to the first alignment electrode 113A and the second alignment electrode 113B.

The capping layer 114 may cover the first alignment electrode 113A and the second alignment electrode 113B disposed in each of the light-emitting element supply areas LAR. According to one or more embodiments of the present disclosure, the capping layer 114 may be formed as an inorganic film containing an inorganic insulating material (e.g., silicon oxide (SiOx), silicon nitride (SiNx), silicon oxynitride (SiOxNy), and/or other inorganic insulating material). According to one or more embodiments of the present disclosure, the capping layer 114 may have hydrophilic properties compared to the bank 112. The area where a pair of first alignment electrodes 113A and second alignment electrodes 113B and the capping layer 114 covering the pair of first alignment electrodes 113A and second alignment electrodes 113B are disposed may be defined as a light-emitting element supply area LAR (or light-emitting element array area).

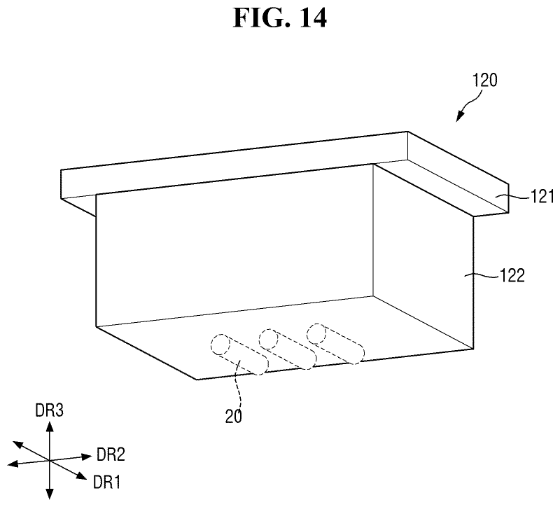

FIG. 14 is a perspective view showing a stamp 120 according to one or more embodiments of the present disclosure.

Referring to FIG. 14 in conjunction with FIGS. 1-13, the stamp 120 transfers the light-emitting elements 20 onto a target substrate 10 (e.g., the lower substrate 10 of the display device DD). It may be a part of a fabrication device (e.g., a transfer device) used to fabricate the display device DD. For example, the stamp 120 may be a pickup device (or transfer substrate) that may be used to pick up the light-emitting elements 20 supplied and/or aligned on the printing substrate 110 and transfer them onto the target substrate 10.

The stamp 120 according to one or more embodiments may include a pickup portion 122 for picking up the light-emitting elements 20. According to one or more embodiments of the present disclosure, the stamp 120 may further include a support portion 121 that supports the pickup portion 122.

The pickup portion 122 may be in contact with and/or coupled with the light-emitting elements 20 on the printing substrate 110 by compression or the like. For example, the pickup portion 122 may separate the light-emitting elements 20 supplied and/or aligned on the printing substrate 110 to attach or transfer them to the surface of the pickup portion 122, and may attach or transfer the light-emitting elements 20 to the target substrate 10. The pickup portion 122 may protrude from the support portion 121 in the third direction DR3.

According to one or more embodiments of the present disclosure, the pickup portion 122 may have a size (e.g., area) equal to or corresponding to at least a portion of the main area MA of the printing substrate 110. The pickup portion 122 may be in contact with the light-emitting elements 20 disposed on at least a part of the main area MA to pick up the light-emitting elements 20, and may transfer the light-emitting elements 20 to the target substrate 10. According to one or more embodiments of the present disclosure, the pickup portion 122 may have an area equal to or greater than at least one light-emitting element supply area LAR defined on the printing substrate 110 (e.g., the light-emitting element supply area LAR in FIG. 11), and/or may have an area equal to or greater than at least one emission area EMA defined in the target substrate 10. Accordingly, the light-emitting elements 20 can be concurrently (e.g., simultaneously) transferred to the emission areas EMA of one or more pixels PX. As an example, because the pickup portion 122 has the area equal to or corresponding to the emission areas EMA defined on the target substrate 10, it is possible to transfer the light-emitting elements 20 concurrently (e.g., simultaneously) to the emission areas EMA of the plurality of pixels PX.

According to one or more embodiments of the present disclosure, the light-emitting elements 20 may be transferred from the printing substrate 110 to the stamp 120 using the surface energy difference, and the light-emitting elements 20 may be transferred back to the target substrate 10. As an example, the surface energy of the stamp 120 (e.g., the surface energy of the pickup portion 122 in contact with the light-emitting elements 20) may be higher than the surface energy of the printing substrate 110 (e.g., the surface energy of the capping layer 114 in contact with the light-emitting elements 20, and may be lower than the surface energy of the target substrate 10 (e.g., the surface energy of the fourth insulating layer 16 in contact with the light-emitting elements 20). According to one or more embodiments of the present disclosure, the pickup portion 122 may be made of a material suitable for utilizing surface energy differences. For example, the pickup portion 122 may be formed of, but is not limited to, a flexible material such as polydimethylsiloxane (PDMS) and/or rubber. For example, the pickup portion 122 may be formed of a hard material such as glass and/or a silicon wafer.

The support portion 121 may be coupled with the pickup portion 122 to support the pickup portion 122. According to one or more embodiments of the present disclosure, the support portion 122 may include the same material as or a different material from the pickup portion 122, and may or may not be formed integrally with the pickup portion 122. According to one or more embodiments of the present disclosure, the support portion 121 may be coupled with a transport device for moving the stamp 120. Accordingly, the stamp 120 can be moved to a desired position.

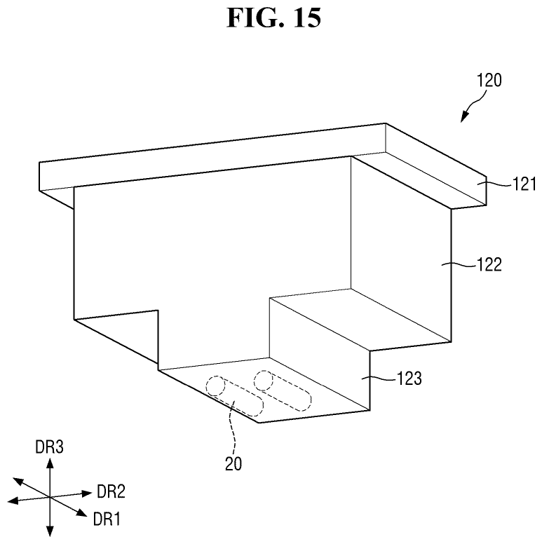

FIG. 15 is a perspective view showing a stamp 120 according to one or more embodiments of the present disclosure.

Referring to FIG. 15 in conjunction with FIGS. 1-14, the stamp 120 according to one or more embodiments may include a precise pickup portion 123 that protrudes from a portion of the pickup portion 122 and has a relatively small area. The precise pickup portion 123 may be used to transfer a smaller number of light-emitting elements 20 to a particular region of a fine size (e.g., a target area that requires repair). For example, the precise pickup portion 123 may be used for smaller emission areas EMA of the pixels PX, but the present disclosure is not limited thereto.

According to one or more embodiments of the present disclosure, if the number of the light-emitting elements 20 is insufficient in at least one emission area EMA, the light-emitting elements 20 may be additionally disposed in the area where the light-emitting elements 20 are insufficient using the precise pickup portion 123. For example, after the light-emitting elements 20 have been disposed in the emission areas EMA of the target substrate 10, the arrangement of the light-emitting elements 20 may be inspected by automatic optical inspection (AOI), etc. As a result of the inspection, if there is an area where the number and/or density of the light-emitting elements 20 is determined to be insufficient (hereinafter referred to as “repair area”), the light-emitting elements 20 may be additionally disposed in the repair area by using the stamp 120 including the precise pickup portion 123.

According to one or more embodiments of the present disclosure, the precise pickup portion 123 may have a size (e.g., an area) equal to or corresponding to at least a portion of the subsidiary area SBA of the printing substrate 110. The precise pickup portion 123 may be in contact with the light-emitting elements 20 disposed on at least a portion of the subsidiary area SBA, and may pick up the light-emitting elements 20 and transfer them to the repair area. In this manner, if there is a defective portion that requires repair in relation to the arrangement of the light-emitting elements 20, it is possible to precisely repair the defective portion by using the precise pickup portion 123.

FIGS. 16-22 are cross-sectional views illustrating a method of fabricating a display device according to one or more embodiments of the present disclosure. For example, FIGS. 16-22 sequentially show a method of fabricating a display device DD including processing steps of disposing the light-emitting elements 20 on the target substrate 10 (e.g., a lower substrate of the display device DD) using a transfer device 100 including the printing substrate 110 according to at least one of the embodiments of FIGS. 10-13 and the stamp 120 according to at least one of the embodiments of FIGS. 14 and 15.

Referring to FIGS. 1-15 and FIGS. 16-22, the transfer device 100 including the printing substrate 110 and the stamp 120 may be prepared. For example, the printing substrate 110 may include a support substrate 111, a bank 112 disposed entirely on the support substrate 111, a first alignment electrode 113A and a second alignment electrode 113B disposed on the bank 112, a capping layer 114 covering the first alignment electrode 113A and the second alignment electrode 113B. In addition, the stamp 120 may include a pickup portion 122 for picking up the light-emitting elements 20 supplied and/or aligned on the printing substrate 110.

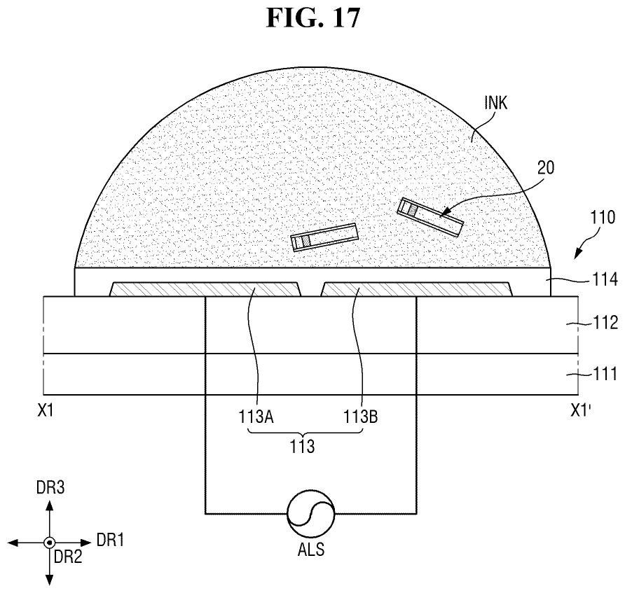

When the transfer device 100 is prepared, an ink INK including the light-emitting elements 20 may be supplied on the printing substrate 110 as shown in FIGS. 16 and 17. According to one or more embodiments of the present disclosure, the ink INK containing the light-emitting elements 20 may be dropped or applied onto the printing substrate 110 by inkjet printing, etc., but the method of supplying the light-emitting elements 20 is not limited to it. For example, the equipment or the method for supplying the light-emitting elements 20 on the printing substrate 110 may vary depending on embodiments.

According to one or more embodiments, the bank 112 may be a liquid-repellent bank. Accordingly, the contact angle between the bank 112 and the ink INK may be large. For example, the contact angle between the bank 112 and the ink INK may be equal to or greater than approximately 60°. The ink INK may be located in the light-emitting element supply area LAR where the first and second alignment electrodes 113A and 113B and the capping layer 114 are disposed.

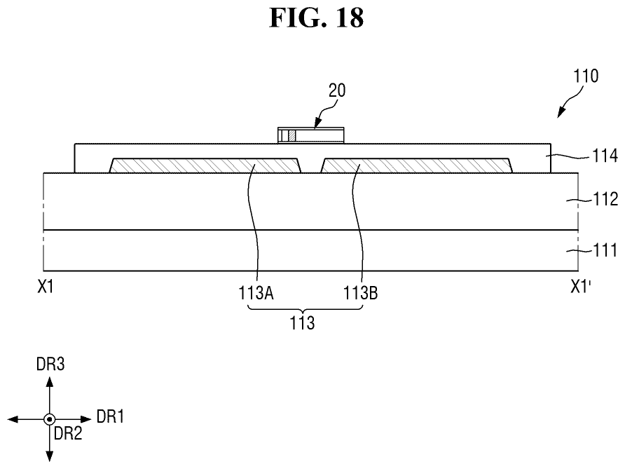

According to one or more embodiments, light-emitting elements 20 may be aligned on the printing substrate 110. For example, as shown in FIGS. 17 and 18, by applying an alignment signal ALS to the first alignment electrode 113A and the second alignment electrode 113B as the ink INK is supplied on the printing substrate 110, the light-emitting elements 20 can be aligned between the first alignment electrode 113A and the second alignment electrode 113B. For example, the light-emitting elements 20 may be aligned between the first alignment electrode 113A and the second alignment electrode 113B so that one of the first and second ends of the light-emitting elements 20 is adjacent to the first alignment electrode 113A and the other is adjacent to the second alignment electrode 113B. If the separation distance between the first alignment electrode 113A and the second alignment electrode 113B is equal to or less than the length of each of the light-emitting elements 20, the light-emitting elements 20 may overlap with the first alignment electrode 113A and/or the second alignment electrode 113B. For example, the first ends of the light-emitting elements 20 may overlap with the first alignment electrode 113A, and the second ends of the light-emitting elements 20 may overlap with the second alignment electrode 113B.

After the light-emitting elements 20 has been aligned, the ink INK may be dried via a drying process. Accordingly, the light-emitting elements 20 may be disposed and/or fixed at aligned positions on the printing substrate 110 as shown in FIG. 18.

The alignment signal ALS may be used to generate an electric field to induce self-alignment of the light-emitting elements 20, and may be a DC or AC signal. The alignment signal ALS may be applied to the first alignment electrode 113A and the second alignment electrode 113B at least while a process of aligning the light-emitting elements 20 is in progress. According to one or more embodiments of the present disclosure, the alignment signal ALS may be applied to the first alignment electrode 113A and the second alignment electrode 113B even during at least some periods of the drying process.

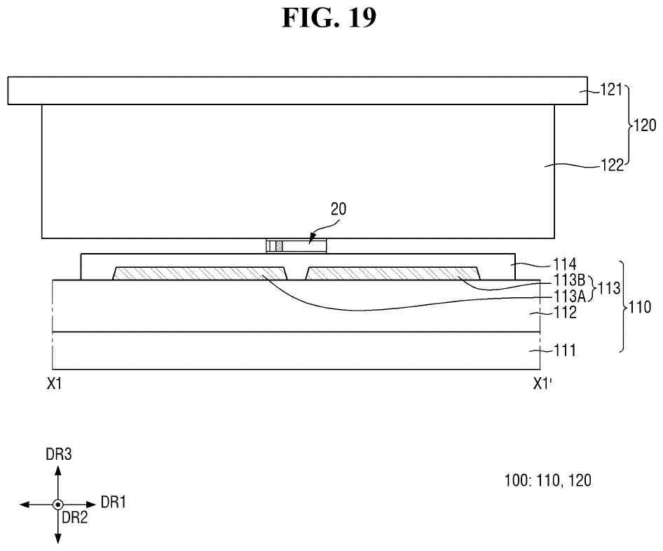

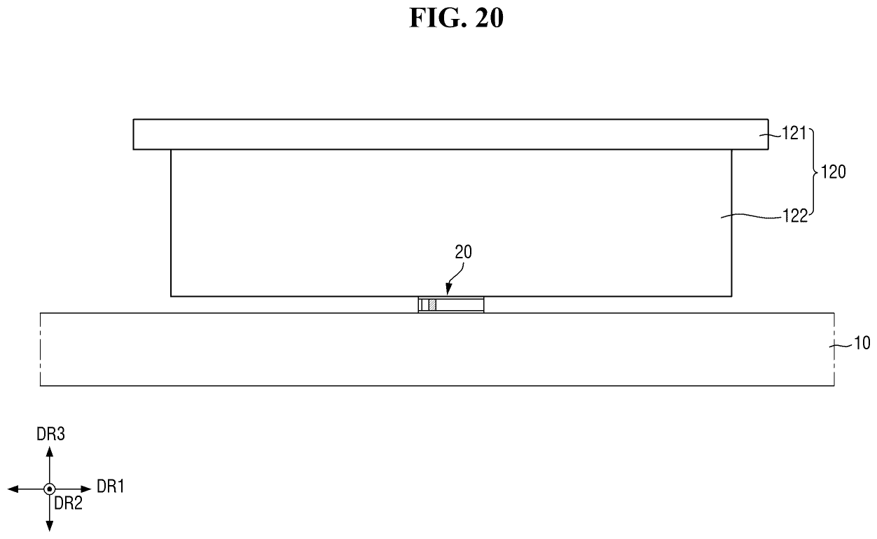

Subsequently, while the light-emitting elements 20 are aligned and/or fixed on the printing substrate 110, the light-emitting elements 20 on the printing substrate 110 may be picked up and/or transferred onto the stamp 120, and then the light-emitting elements 20 transferred on the stamp 120 may be transferred to the target substrate 10. For example, as shown in FIG. 19, the stamp 120 may be placed on the printing substrate 110, and the pickup portion 122 of the stamp 120 may be pressed on the light-emitting elements 20, such that the light-emitting elements 20 may be transferred onto the pickup portion 122 of the stamp 120. According to one or more embodiments, due to the difference between the surface energy of the printing substrate 110 (e.g., the surface energy of the capping layer 114) and the surface energy of the stamp 120 (e.g., the surface energy of the pickup portion 122), the light-emitting elements 20 can be easily picked up with the stamp 120 on the printing substrate 110. Subsequently, as shown in FIG. 20, the stamp 120 may be placed on the target substrate 10, and the light-emitting elements 20 may be pressed on the target substrate 10 to transfer the light-emitting elements 20 to the target substrate 10. According to one or more embodiments, due to the difference between the surface energy of the stamp 120 (e.g., the surface energy of the pickup portion 122) and the surface energy of the target substrate 10 (e.g., the surface energy of the fourth insulating layer 16 of FIG. 4 or the adhesive layer 50 of FIG. 7), the light-emitting elements 20 can be easily transferred from the stamp 120 to the target substrate 10. According to one or more embodiments of the present disclosure, the light-emitting elements 20 may be disposed and/or transferred to an appropriate location on the target substrate 10 (e.g., the emission area EMA of each of the pixels PX) using alignment marks, etc.

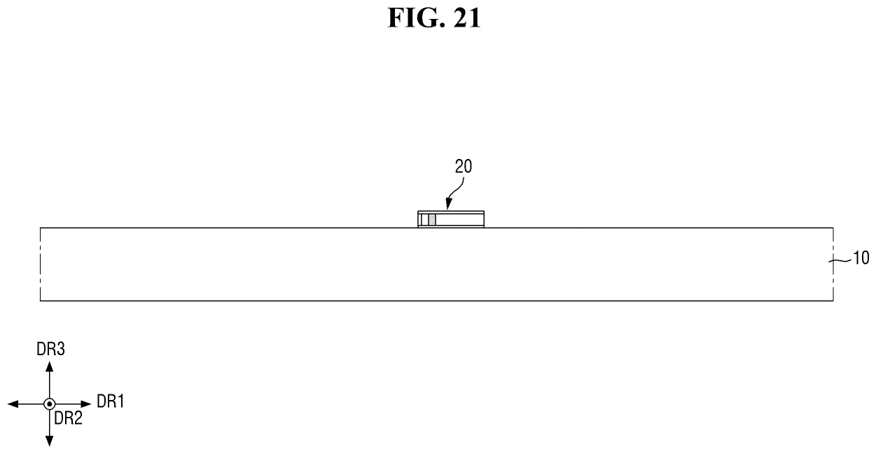

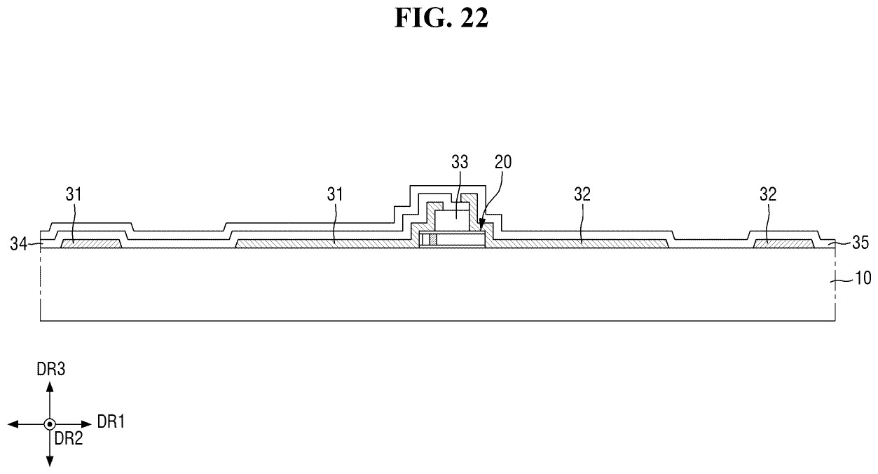

Once the light-emitting elements 20 are properly transferred to the target substrate 10, the stamp 120 may be removed from the target substrate 10 as shown in FIG. 21, and a subsequent pixel process may be performed. For example, as shown in FIG. 22, a first electrode 31, a second electrode 32, a fifth insulating layer 33, a sixth insulating layer 34, and/or a seventh insulating layer 35 may be formed on the target substrate 10 on which the light-emitting elements 20 are disposed. According to one or more embodiments, the first electrode 31 and the second electrode 32 may be formed on the both ends of the light-emitting elements 20. For example, the first electrode 31 and the second electrode 32 may be formed separately from each other on different ends of the light-emitting elements 20. Accordingly, the display device DD according to one or more embodiments can be fabricated.

As described above, according to one or more embodiments, using the printing substrate 110 including the alignment electrodes 113 and the stamp 120 including at least one pickup portion 122, the light-emitting elements 20 may be supplied and aligned on the printing substrate 110, and then may be picked up with the stamp 120 and transferred to the target substrate 10. The target substrate 10 to which the aligned light-emitting elements 20 are transferred may be the lower substrate 10 of the display device DD, and no alignment electrodes for aligning the light-emitting elements 20 may be formed on the lower substrate 10 of the display device DD. Accordingly, it is possible to reduce damage to the lines formed in the lower substrate 10 of the display device DD, and to improve the alignment of the light-emitting elements 20.

In addition, according to one or more embodiments, the light-emitting elements 20 supplied and aligned on the printing substrate 110 may be picked up using the stamp 120 and then transferred to the target substrate 10, instead of being transferred directly to the target substrate 10. By doing so, the high-resolution and/or large-area display device DD can be easily fabricated.

For example, even if the alignment electrodes 113 are arranged on the printing substrate 110 with a resolution different from that of the display device DD, the light-emitting elements 20 aligned on the printing substrate 110 can be properly transferred to the target position of the target substrate 10 using the stamp 120. For example, in FIG. 12, the light-emitting elements 20 supplied and aligned in two light-emitting element supply areas LAR sequentially arranged along the first direction DR1, e.g., the light-emitting element supply area LAR of the first column and the light-emitting element supply area LAR of the second column may be picked up concurrently (e.g., simultaneously) with the stamp 120, and may be transferred concurrently (e.g., simultaneously) to at least one emission area EMA located in the first column of FIG. 3 and at least one emission area EMA located in the third column of FIG. 3. For example, in FIG. 12, the light-emitting elements 20 supplied and aligned in two different light-emitting element supply areas LAR sequentially arranged along the first direction DR1, e.g., the light-emitting element supply area LAR of the third column and the light-emitting element supply area LAR of the fourth column may be picked up concurrently (e.g., simultaneously) with the stamp 120, and may be transferred concurrently (e.g., simultaneously) to at least one emission area EMA located in the second column of FIG. 3 and at least one emission area EMA located in the fourth column of FIG. 3. In this instance, even though the emission areas EMA of the target substrate 10 have twice the resolution of the light-emitting element supply areas LAR of the printing substrate 110 in the first direction DR1, the light-emitting elements 20 on the printing substrate 110 can be properly transferred onto the target substrate 10 using the stamp 120. In this way, the light-emitting elements 20 aligned on the printing substrate 110 can be properly selected and selectively transferred to desired locations on the target substrate 10 using the stamp 120. Accordingly, the light-emitting elements 20 can be properly disposed on the target substrate 10 having a higher resolution than the resolution of the printing substrate 110 (e.g., a resolution N times the resolution of the printing substrate 110), where N is a natural number. Therefore, according to one or more embodiments, the high-resolution display device DD can be easily fabricated regardless of the resolution limit of the inkjet process depending on the structure of the inkjet printing equipment used in the inkjet process for supplying the light-emitting elements 20. In addition, by disposing the light-emitting elements 20 on the printing substrate 110 onto the target substrate 10 using the stamp 120, instead of transferring them from the printing substrate 110 to each target substrate 10, a large-area display device DD can be easily fabricated. For example, using the printing substrate 110 with the area and/or resolution different from those of the lower substrate 10 of the display device DD, it is possible to properly dispose the light-emitting elements 20 on the lower substrate 10 of the display device DD.

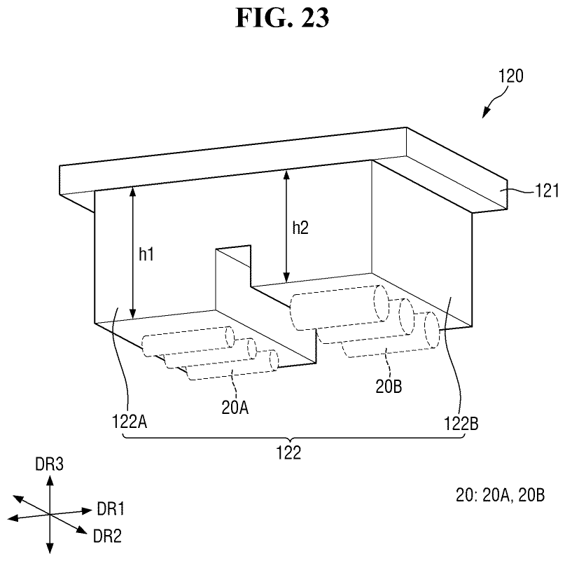

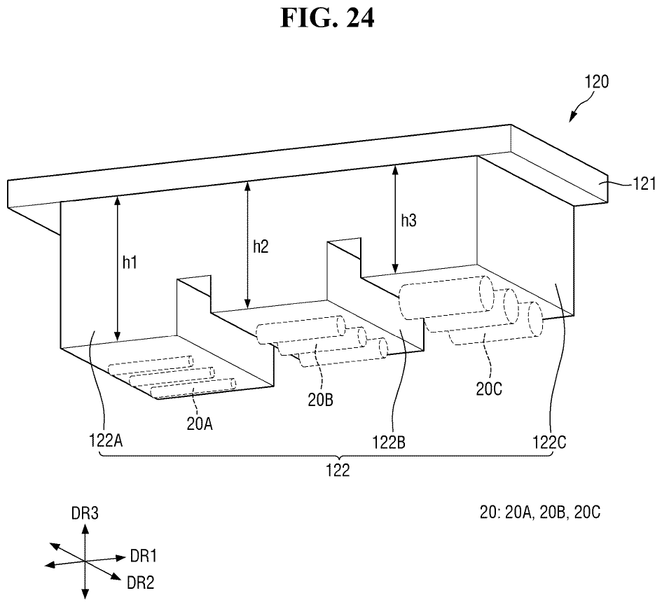

FIG. 23 is a perspective view showing a stamp 120 according to one or more embodiments of the present disclosure. FIG. 24 is a perspective view showing a stamp 120 according to one or more embodiments of the present disclosure. For example, FIGS. 23 and 24 show different embodiments with respect to the number of pickup portions 122 having different heights.

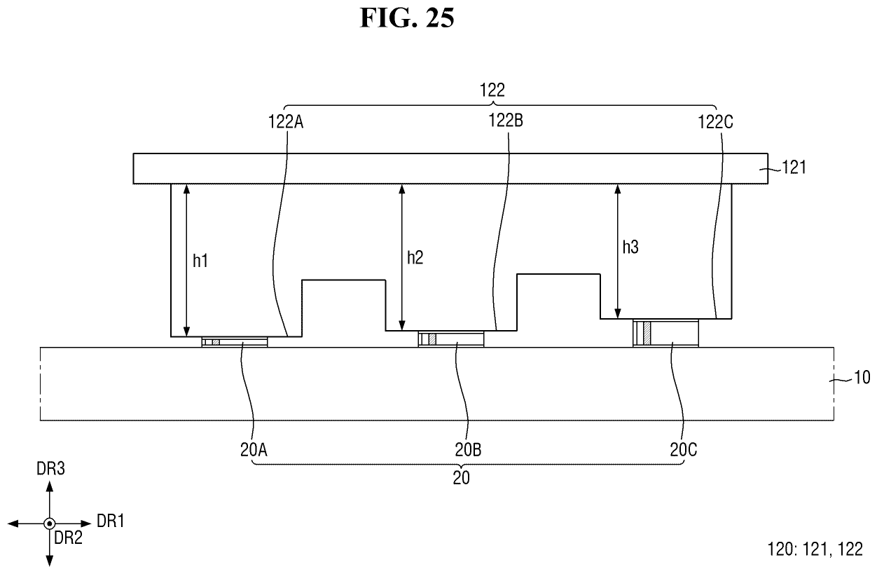

FIG. 25 is a cross-sectional view showing a method of concurrently (e.g., simultaneously) transferring light-emitting elements 20 of different sizes using a stamp 120 according to one or more embodiments. For example, FIG. 25 shows a processing step in which light-emitting elements 20 having different diameters are concurrently (e.g., simultaneously) transferred to the target substrate 10 using the stamp 120 according to the embodiment of FIG. 24.

Referring to FIGS. 23-25 in conjunction with FIGS. 1-22, the stamp 120 may include at least two pickup portions 122 having different heights. For example, the stamp 120 may include a first pickup portion 122A having a first height h1 and a second pickup portion 122B having a second height h2 with respect to a support portion 121 as shown in FIG. 23. According to one or more embodiments of the present disclosure, the first pickup portion 122A and the second pickup portion 122B may be adjacent to each other in the first direction DR1. For example, the first pickup portion 122A and the second pickup portion 122B may be spaced from each other by the distance equal to or corresponding to the distance between two adjacent light-emitting element areas LAR in the first direction DR1 from among the light-emitting element supply areas LAR provided on the printing substrate 110. It should be understood, however, that the present disclosure is not limited thereto. The sizes and/or orientations of the pickup portions 122 may vary depending on embodiments.

The light-emitting elements 20 having different diameters (or widths) may be concurrently (e.g., simultaneously) picked up and/or transferred using the stamp 120 including the pickup portions 122 of different heights. As an example, by using the first pickup portion 122A of the first height h1, it is possible to pick up and transfer first light-emitting elements 20A that are located in at least one light-emitting element supply area LAR (hereinafter referred to as “first light-emitting element array area”) and have a relatively small diameter. In addition, by using the second pickup portion 122B of the second height h2 smaller than the first height h1, it is possible to pick up and transfer second light-emitting elements 20B that are located in at least one other light-emitting element supply area LAR adjacent to the first light-emitting element supply area in the first direction DR1 (hereinafter referred to as “second light-emitting element array area”) and have a relatively larger diameter. According to one or more embodiments of the present disclosure, the first light-emitting elements 20A and the second light-emitting elements 20B may be concurrently (e.g., simultaneously) transferred from the printing substrate 110 onto the first pickup portion 122A and the second pickup portion 122B, and may be concurrently (e.g., simultaneously) transferred from the first pickup portion 122A and the second pickup portion 122B onto the target substrate 10. For example, the printing substrate 110 may include a plurality of light-emitting element supply areas LAR including a first light-emitting element supply area and a second light-emitting element supply area adjacent to each other in the first direction DR1, and may pick up the light-emitting elements 20 of different sizes (e.g., different diameters) supplied to the first light-emitting element supply area and the second light-emitting element supply area onto at least two pickup portions 122 of different heights to transfer them onto the target substrate 10 concurrently (e.g., simultaneously).

According to one or more embodiments of the present disclosure, the stamp 120 may include pickup portions 122 having three or more different heights. For example, the stamp 120 may include the first pickup portion having the first height h1, the second pickup portion having the second height h2, and the third pickup portion having the third height h3 with respect to the support portion 121, as shown in FIG. 24.

According to one or more embodiments of the present disclosure, the first pixel PX1, the second pixel PX2, and the third pixel PX3 may include light-emitting elements 20 having different diameters. For example, the first pixel PX1 may include first light-emitting elements 20A (e.g., blue light-emitting elements) having a relatively small diameter, the second pixel PX2 may include second light-emitting elements 20B (e.g., green light-emitting elements) having a medium diameter, and the third pixel PX3 may include third light-emitting elements 20C (e.g., red light-emitting elements) having a larger diameter than the first and second light-emitting elements 20A and 20B.

According to one or more embodiments of the present disclosure, using the stamp 120 including the first pickup portion 122A, the second pickup portion 122B, and the third pickup portion 122C, the light-emitting elements 20 of the first pixel PX1, the second pixel PX2, and the third pixel PX3 that are adjacent to one another can be concurrently (e.g., simultaneously) picked up and transferred. For example, the first light-emitting elements 20A may be picked up and transferred using the first pickup portion 122A, the second light-emitting elements 20B may be picked up and transferred using the second pickup portion 122B, and the third light-emitting elements 20C may be picked up and transferred using the third pickup portion 122C. For example, as shown in FIG. 25, the first light-emitting elements 20A, the second light-emitting elements 20B, and the third light-emitting elements 20C may be picked up by the first pickup portion 122A, the second pickup portion 122B, and the third pickup portion 122C, respectively, and may be concurrently (e.g., simultaneously) transferred onto the target substrate 10.

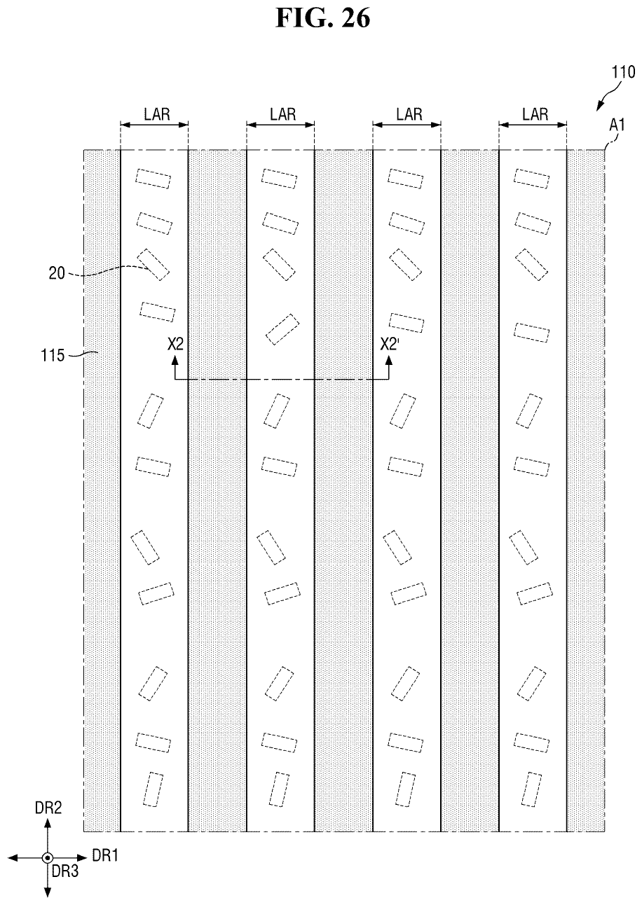

FIG. 26 is a plan view showing a printing substrate 110 according to one or more embodiments of the present disclosure. For example, FIG. 26 shows a portion of the printing substrate 110 corresponding to area A1 of FIG. 10. The embodiment of FIG. 26 is different from the embodiments of FIGS. 11 and 12 with respect to the patterns provided on the printing substrate 110.

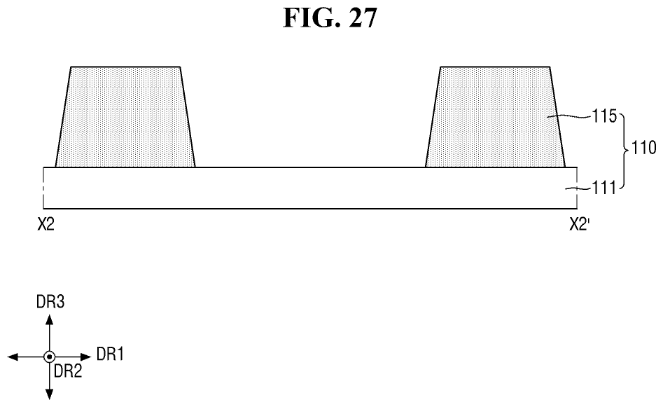

FIG. 27 is a cross-sectional view showing a printing substrate 110 according to one or more embodiments of the present disclosure. For example, FIG. 27 shows a cross-section of the printing substrate 110 taken along the line X2-X2′ of FIG. 26.

Referring to FIGS. 26 and 27 in conjunction with FIGS. 1-10, the printing substrate 110 according to one or more embodiments may include a support substrate 111 and a bank 115 disposed on the support substrate 111. According to one or more embodiments of the present disclosure, the printing substrate 110 may not include the alignment electrodes 113 according to the above-described embodiments.

According to one or more embodiments of the present disclosure, the bank 115 may define and/or partition at least one light-emitting element supply area LAR on the printing substrate 110. For example, the bank 115 may be disposed on the printing substrate 110 and may define and/or partition a plurality of light-emitting element supply areas LAR. The bank 115 may be disposed between and/or around the light-emitting element supply areas LAR. According to one or more embodiments of the present disclosure, the bank 115 may have the shape of a dam surrounding each of the light-emitting element supply areas LAR. According to one or more embodiments of the present disclosure, the bank 115 may be a liquid-repellent bank. Accordingly, the ink INK supplied on the printing substrate 110 can smoothly flow into the light-emitting element supply areas LAR. In addition, by disposing the bank 115 on the printing substrate 110, it is possible to appropriately adjust the amount of the supplied ink INK. As a result, the ink INK can be used more efficiently. In this manner, the efficiency of using the ink INK can be increased and the fabrication costs can be saved.

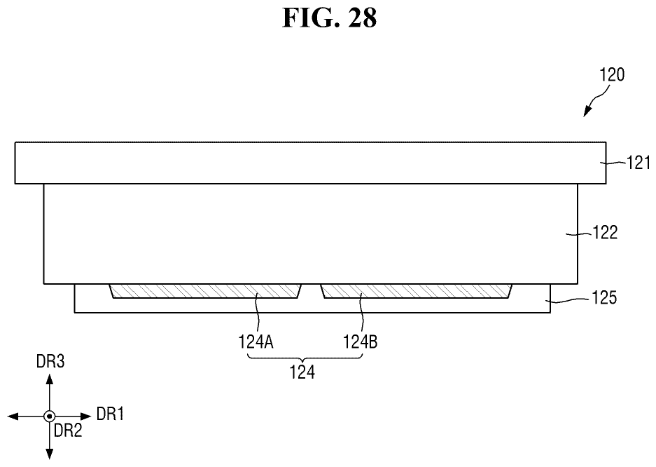

FIG. 28 is a cross-sectional view showing a stamp 120 according to one or more embodiments of the present disclosure.

Referring to FIG. 28 in conjunction with FIGS. 1-15, the stamp 120 may further include alignment electrodes 124 and a capping layer 125. The alignment electrodes 124 and the capping layer 125 may be disposed on a surface of the pickup portion 122 that faces the printing substrate 110 and the target substrate 10.

For example, the stamp 120 may include a first alignment electrode 124A and a second alignment electrode 124B disposed adjacent to each other on the pickup portion 122, and a capping layer 125 covering the first alignment electrode 124A and the second alignment electrode 124B. According to one or more embodiments of the present disclosure, the first alignment electrode 124A and the second alignment electrode 124B may be spaced from each other in the first direction DR1 and may be extended in the second direction DR2.

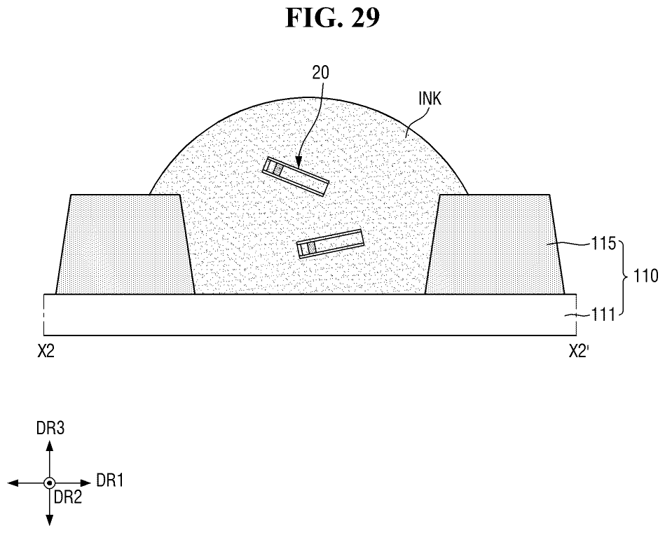

FIGS. 29-32 are cross-sectional views illustrating a method of fabricating a display device according to one or more embodiments of the present disclosure. For example, FIGS. 29-32 sequentially show a method of fabricating a display device DD including processing steps of disposing the light-emitting elements 20 on the target substrate 10 using the transfer device 100 including the printing substrate 110 according to one or more embodiments of FIGS. 26 and 27 and the stamp 120 according to the embodiment of FIG. 28. As an example, FIGS. 29-32 sequentially show processing steps of disposing the light-emitting elements 20 on the target substrate 10 using a printing substrate 110 including a bank 115 defining light-emitting element supply areas LAR and a stamp 120 including alignment electrodes 124.

Referring to FIGS. 1-9 and FIGS. 26-32, a transfer device 100 including a printing substrate 110 and a stamp 120 may be prepared. For example, a printing substrate 110 may be prepared which includes a support substrate 111 and a bank 115 disposed on the support substrate 111 to partition and/or define light-emitting element supply areas LAR. In addition, a stamp 120 may be prepared, which includes a pickup portion 122, a first alignment electrode 124A and a second alignment electrode 124B disposed adjacent to each other on the pickup portion 122, and a capping layer 125 covering the first alignment electrode 124A and the second alignment electrode 124B.

When the transfer device 100 is prepared, an ink INK including light-emitting elements 20 may be supplied on the printing substrate 110 as shown in FIG. 29. According to one or more embodiments of the present disclosure, the ink INK containing the light-emitting elements 20 may be dropped or applied onto the printing substrate 110 by inkjet printing, etc. According to one or more embodiments, the bank 115 may be a liquid-repellent bank, and each of the light-emitting element supply areas LAR defined by the bank 115 may be filled with the ink INK.

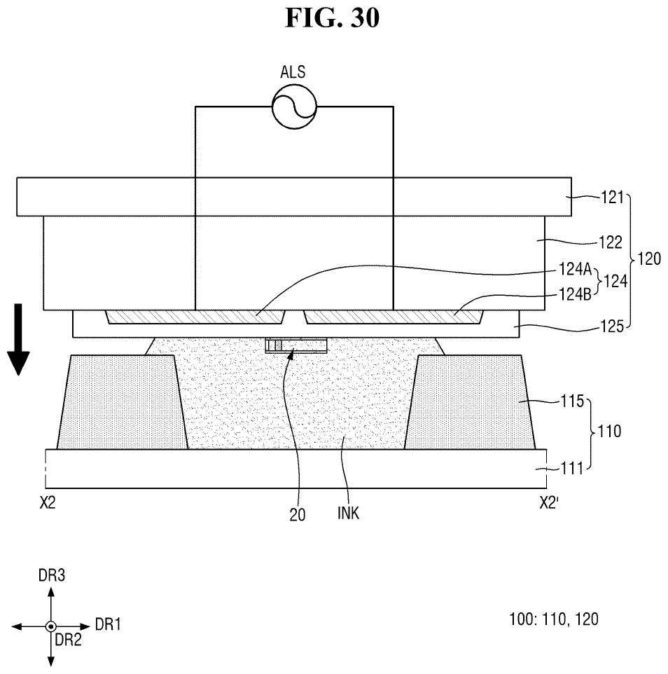

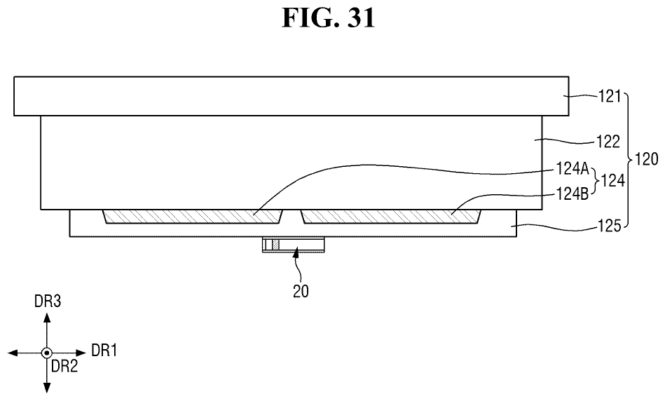

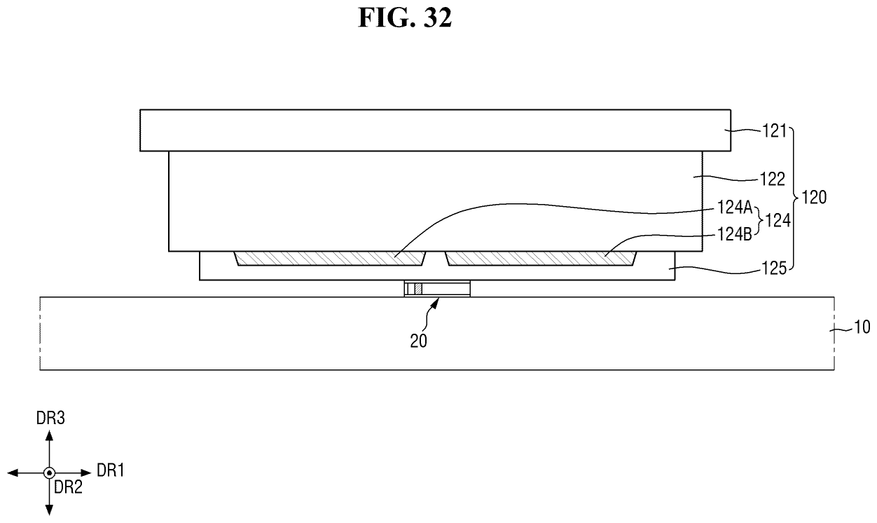

Subsequently, as shown in FIGS. 30-32, the light-emitting elements 20 on the printing substrate 110 may be picked up and aligned using the stamp 120, and the light-emitting elements 20 may be transferred onto the target substrate 10. For example, as shown in FIG. 30, the stamp 120 having the light-emitting elements 20 attached thereto may be placed on the printing substrate 110, and the stamp 120 may be lowered in the direction indicated by the arrow to bring the stamp 120 into contact with the ink INK on the printing substrate 110. Then, an alignment signal ALS may be applied to the first alignment electrode 124A and the second alignment electrode 124B while the stamp 120 is in contact with the ink INK. Accordingly, the light-emitting elements 20 can be aligned on the pickup portion 122. For example, the light-emitting elements 20 may be in contact with the capping layer 125 on the surface of the pickup portion 122 where the first alignment electrode 124A and the second alignment electrode 124B are disposed, and may be aligned between the first alignment electrode 124A and the second alignment electrode 124B. After the light-emitting elements 20 has been aligned, the ink INK may be dried. Accordingly, as shown in FIG. 31, the light-emitting elements 20 may be placed and/or fixed on the pickup portion 122 of the stamp 120. According to one or more embodiments of the present disclosure, while the process of drying the ink INK is in progress, the alignment signal ALS is applied to the first alignment electrode 124A and the second alignment electrode 124B, so that the light-emitting elements 20 may be stably placed and/or fixed at the aligned positions on the stamp 120. Subsequently, as shown in FIG. 32, the stamp 120 may be placed on the target substrate 10, and the light-emitting elements 20 may be transferred onto the target substrate 10. According to one or more embodiments, the light-emitting elements 20 can be easily transferred by the difference between the surface energy of the stamp 120 and the surface energy of the target substrate 10. For example, the surface energy of the stamp 120 may be lower than the surface energy of the target substrate 10.

Once the light-emitting elements 20 are properly transferred to the target substrate 10, the stamp 120 may be removed from the target substrate 10, and a subsequent pixel process may be performed. In this manner, the display device DD according to one or more embodiments may be fabricated.

As described above, according to one or more embodiments, using the printing substrate 110 including the bank 115 and the stamp 120 including the alignment electrodes 124, the light-emitting elements 20 may be supplied on the printing substrate 110, and then may be aligned on the stamp 120 and transferred to the target substrate 10. The target substrate 10 on which the aligned light-emitting elements 20 are transferred may be the lower substrate 10 of the display device DD and may include no separate alignment electrodes. Accordingly, it is possible to reduce damage to the lines formed in the lower substrate 10 of the display device DD, and to improve the alignment of the light-emitting elements 20.

In addition, according to one or more embodiments, the light-emitting elements 20 may be aligned using the stamp 120 and then transferred to the target substrate 10, instead of being directly transferred to the target substrate 10. By doing so, the high-resolution display device DD can be easily fabricated. For example, a high-resolution display device having a resolution higher than that of the printing substrate 110 (e.g., N times the resolution) can be easily fabricated.

In concluding the detailed description, those skilled in the art will appreciate that many variations and modifications can be made to the embodiments without substantially departing from the principles and scope of the present disclosure. Therefore, the described embodiments of the present disclosure are used in a generic and descriptive sense only and not for purposes of limitation.

What is claimed is:

1. A method of fabricating a display device, the method comprising:
preparing a transfer device comprising a printing substrate and a stamp;
supplying an ink containing light-emitting elements onto the printing substrate;
picking up the light-emitting elements with the stamp; and
transferring the light-emitting elements to a target substrate,
the light-emitting elements being aligned on the printing substrate or the stamp.

2. The method of claim 1, wherein the preparing the transfer device comprises:
preparing the stamp comprising a first alignment electrode and a second alignment electrode; and
a capping layer covering the first alignment electrode and the second alignment electrode.

3. The method of claim 2, wherein the picking up the light-emitting elements with the stamp comprises:
aligning the light-emitting elements by bringing the stamp into contact with the ink on the printing substrate and applying an alignment signal to the first alignment electrode and the second alignment electrode; and
drying the ink and fixing the light-emitting elements on the stamp.

4. The method of claim 2, wherein the preparing the transfer device comprises:
preparing the printing substrate comprising a support substrate and a bank on the support substrate, the bank defining a light-emitting element supply area.

5. The method of claim 1, wherein the preparing the transfer device comprises:
preparing the printing substrate comprising at least two light-emitting element supply areas adjacent to each other in a first direction; and
preparing the stamp comprising at least two pickup portions adjacent to each other in the first direction and having different heights.

6. The method of claim 5, wherein the picking up the light-emitting elements with the stamp comprises:
picking up light-emitting elements of different sizes supplied to the at least two light-emitting element supply areas on the at least two pickup portions, respectively.

7. The method of claim 6, wherein the transferring the light-emitting elements to the target substrate comprises:
concurrently transferring the light-emitting elements of different sizes to the target substrate.

8. The method of claim 1, wherein the preparing the transfer device comprises:
preparing the printing substrate comprising a support substrate, a liquid-repellent bank located entirely on the support substrate, a first alignment electrode and a second alignment electrode on the liquid-repellent bank, and a capping layer covering the first alignment electrode and the second alignment electrode.

9. The method of claim 8, wherein the aligning the light-emitting elements comprises:
aligning the light-emitting elements by applying an alignment signal to the first alignment electrode and the second alignment electrode as the ink is supplied on the printing substrate; and
drying the ink.

10. The method of claim 9, wherein the picking up the light-emitting elements with the stamp comprises:
transferring the light-emitting elements to the stamp, the light-emitting elements being aligned on the printing substrate.

11. The method of claim 1, further comprising:
forming a first electrode and a second electrode on both ends of the light-emitting elements on the target substrate after the transferring the light-emitting elements to the target substrate.

12. An apparatus for fabricating a display device, the apparatus comprising:
a printing substrate comprising light-emitting element supply areas; and
a stamp comprising a pickup portion for picking up light-emitting elements supplied on the printing substrate,
wherein one of the printing substrate and the stamp comprises a first alignment electrode, a second alignment electrode, and a capping layer covering the first alignment electrode and the second alignment electrode.

13. The apparatus of claim 12, wherein the first alignment electrode, the second alignment electrode, and the capping layer are on the pickup portion of the stamp.

14. The apparatus of claim 13, wherein the printing substrate comprises a support substrate and a bank on the support substrate, the bank partitioning the light-emitting element supply areas.

15. The apparatus of claim 12, wherein the pickup portion comprises a first pickup portion and a second pickup portion having different heights.

16. The apparatus of claim 15, wherein the printing substrate includes a plurality of light-emitting element supply areas arranged along at least a first direction.

17. The apparatus of claim 16, wherein the first pickup portion and the second pickup portion are spaced from each other by a distance corresponding to a distance between two light-emitting element supply areas adjacent each other in the first direction.

18. The apparatus of claim 12, wherein the first alignment electrode, the second alignment electrode, and the capping layer are at the printing substrate.

19. The apparatus of claim 18, wherein the printing substrate further comprises:
a support substrate and a liquid-repellent bank located entirely on the support substrate.

20. The apparatus of claim 19, wherein the first alignment electrode, the second alignment electrode, and the capping layer are on a portion of the liquid-repellent bank and expose another portion of the liquid-repellent bank.
